(19) United States
(12) Patent Application Publication
(10) Pub. No.: US 2024/0215324 A1
(43) Pub. Date: Jun. 27, 2024

(54) DISPLAY DEVICE

(71) Applicant: Samsung Display Co., LTD., Yongin-si (KR)

(72) Inventor: SEUNG-LYONG BOK, Yongin-si (KR)

(21) Appl. No.: 18/374,284

(22) Filed: Sep. 28, 2023

(30) Foreign Application Priority Data
Dec. 23, 2022 (KR) 10-2022-0183087

(51) Int. Cl. H10K 59/122; H10K 59/131; H10K 59/40; H10K 59/80

(52) U.S. Cl. CPC H10K 59/122; H10K 59/131; H10K 59/40; H10K 59/873

(57) ABSTRACT

A display device includes a base layer, a circuit layer disposed on the base layer, an anode disposed on the circuit layer, a pixel defining layer disposed on the circuit layer, where a light emitting opening is defined in the pixel defining layer to overlap the anode, a barrier wall disposed on the pixel defining layer, where a barrier opening is defined in the barrier wall to overlap the light emitting opening, a thin film encapsulation layer disposed over the circuit layer to cover the anode, the pixel defining layer, and the barrier wall, and a plurality of touch electrodes disposed between the circuit layer and the thin film encapsulation layer.

This application claims priority to Korean Patent Application No. 10-2022-0183087, filed on Dec. 23, 2022, and all the benefits accruing therefrom under 35 U.S.C. § 119, the content of which in its entirety is herein incorporated by reference.

### BACKGROUND

### 1. Field

Embodiments of the disclosure described herein relate to a display device, and more particularly, relate to a display device having improved display quality.

### 2. Description of the Related Art

A display device, such as a television, a monitor, a smart phone, a tablet computer, or the like, which provides an image to a user includes a display panel that displays an image. Various display panels, such as a liquid crystal display panel, an organic light emitting display panel, an electrowetting display panel, and an electrophoretic display panel, are being developed.

The organic light emitting display panel may include anodes, cathodes, and emission patterns. The emission patterns may be separated for respective emissive regions, and the cathodes may provide a common voltage for the respective emissive regions.

### SUMMARY

Embodiments of the disclosure provide a display device having improved display quality in which light emitting elements are formed without using a metal mask.

According to an embodiment, a display device includes a base layer, a circuit layer disposed on the base layer, an anode disposed on the circuit layer, a pixel defining layer disposed on the circuit layer, where a light emitting opening is defined in the pixel defining layer to overlap the anode, a barrier wall disposed on the pixel defining layer, where a barrier opening is defined in the barrier wall to overlap the light emitting opening, a thin film encapsulation layer disposed over the circuit layer to cover the anode, the pixel defining layer, and the barrier wall, and a plurality of touch electrodes disposed between the circuit layer and the thin film encapsulation layer.

In an embodiment, the display device may further include an emission pattern disposed on the anode and a cathode disposed on the emission pattern and in contact with the barrier wall.

In an embodiment, the cathode may include a plurality of cathodes, and each of the plurality of touch electrodes may include a corresponding cathode among the plurality of cathodes.

In an embodiment, the barrier wall may include a plurality of barrier wall patterns spaced apart from each other.

In an embodiment, each of the plurality of touch electrodes may include a corresponding barrier wall pattern among the plurality of barrier wall patterns.

In an embodiment, a common voltage may be provided to the plurality of touch electrodes in a first mode, and a touch sensing signal may be provided to the plurality of touch electrodes in a second mode different from the first mode.

In an embodiment, each of the plurality of touch electrodes may be electrically connected with a first transistor and a second transistor, and the first transistor may transfer the common voltage to the plurality of touch electrodes in the first mode and may transfer the touch sensing signal to the plurality of touch electrodes in the second mode.

In an embodiment, the display device may further include a plurality of trace lines electrically connected with the plurality of touch electrodes.

In an embodiment, each of the plurality of trace lines may be disposed in a same layer as the anode and may include a same material as the anode.

In an embodiment, Each of the plurality of trace lines may include a first sub-layer disposed in a same layer as the anode and including a same material as the anode and a second sub-layer disposed under the first sub-layer and electrically connected with the first sub-layer, where the second sub-layer may be included in the circuit layer.

In an embodiment, the plurality of touch electrodes may be disposed over the barrier wall and may be insulated from the barrier wall.

In an embodiment, the display device may further include an insulating layer disposed between the plurality of touch electrodes and the barrier wall.

In an embodiment, the plurality of touch electrodes may include a first touch electrode and a second touch electrode. In such an embodiment, the first touch electrode may include a sensing pattern and a bridge pattern, and the bridge pattern may be disposed in a same layer as the anode and may include a same material as the anode.

In an embodiment, the display device may further include a protrusion surrounding at least a portion of a hole defined in the base layer in a plan view, and the protrusion may include a same material as the barrier wall.

According to an embodiment, a display device includes a base layer, a circuit layer disposed on the base layer, a plurality of anodes disposed on the circuit layer, a pixel defining layer disposed on the circuit layer, where light emitting openings are defined in the pixel defining layer to overlap the plurality of anodes, a barrier wall disposed on the pixel defining layer, where barrier openings are defined in the barrier wall to overlap the light emitting openings, a plurality of intermediate layers disposed on the plurality of anodes and accommodated in the light emitting openings, and an electrode layer disposed on the plurality of intermediate layers. In such an embodiment, a common voltage is provided to the electrode layer in a first mode, and a touch sensing signal is provided to the electrode layer in a second mode different from the first mode.

In an embodiment, the barrier wall may include a plurality of barrier wall patterns spaced apart from each other, and the electrode layer may include a plurality of touch electrodes, each of which is electrically connected with a corresponding barrier wall pattern among the plurality of barrier wall patterns.

In an embodiment, each of the plurality of touch electrodes may be electrically connected with a first transistor and a second transistor, and the first transistor may transfer the common voltage to the plurality of touch electrodes in the first mode and may transfer the touch sensing signal to the plurality of touch electrodes in the second mode.

In an embodiment, the display device may further include a plurality of trace lines electrically connected with the plurality of touch electrodes, and each of the plurality of trace lines may be disposed in a same layer as the plurality of anodes and may include a same material as the plurality of anodes.

In an embodiment, the display device may further include a plurality of trace lines electrically connected with the plurality of touch electrodes. Each of the plurality of trace lines may include a first sub-layer disposed in a same layer as the plurality of anodes and including a same material as the plurality of anodes and a second sub-layer disposed under the first sub-layer and electrically connected with the first sub-layer, where the second sub-layer may be included in the circuit layer.

In an embodiment, the plurality of touch electrodes may include a first touch electrode and a second touch electrode. In such an embodiment, the first touch electrode may include a sensing pattern and a bridge pattern, and the bridge pattern may be disposed in a same layer as the plurality of anodes and may include a same material as the plurality of anodes.

In an embodiment, the display device may further include a protrusion surrounding at least a portion of a hole defined in the base layer in a plan view, and the protrusion may include a same material as the barrier wall.

### BRIEF DESCRIPTION OF THE DRAWINGS

The above and other features of the disclosure will become apparent by describing in detail embodiments thereof with reference to the accompanying drawings.

FIG. 1A is a perspective view of a display device according to an embodiment of the disclosure.

FIG. 1B is an exploded perspective view of the display device according to an embodiment of the disclosure.

FIG. 2 is a plan view of a display panel according to an embodiment of the disclosure.

FIG. 3 is an equivalent circuit diagram of a pixel according to an embodiment of the disclosure.

FIG. 4 is a sectional view of the display panel according to an embodiment of the disclosure.

FIG. 5 is a plan view illustrating a plurality of touch electrodes of the display panel according to an embodiment of the disclosure.

FIG. 6 is a sectional view of the display panel taken along line I-I′ of FIG. 5.

FIG. 7 is a sectional view of the display panel taken along line II-II′ of FIG. 5.

FIG. 8A is a plan view illustrating a part of a plurality of touch electrodes of a display panel according to an embodiment of the disclosure.

FIG. 8B is a sectional view of the display panel taken along line III-III′ of FIG. 8A.

FIG. 9 is a sectional view of the display panel taken along line I-I′ of FIG. 5.

FIG. 10 is a plan view illustrating a plurality of touch electrodes of a display panel according to an embodiment of the disclosure.

FIG. 11 is a sectional view taken along line IV-IV′ of FIG. 10.

FIG. 12 is a sectional view of a portion of a display panel according to an embodiment of the disclosure.

FIG. 13A is a perspective view of a display device according to an embodiment of the disclosure.

FIG. 13B is a sectional view of a display panel taken along line V-V of FIG. 13A.

FIGS. 14A to 14G are sectional views illustrating a part of processes of a display panel manufacturing method according to an embodiment of the disclosure.

FIG. 15 is a sectional view illustrating a part of the processes of the display panel manufacturing method according to an embodiment of the disclosure.

FIGS. 16A to 16F are sectional views illustrating a part of the processes of the display panel manufacturing method according to an embodiment of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, when it is mentioned that a component (or, a region, a layer, a part, etc.) is referred to as being “on”, “connected to” or “coupled to” another component, this means that the component may be directly on, connected to, or coupled to the other component or a third component may be present therebetween. In contrast, when an element is referred to as being “directly on” another element, there are no intervening elements present.

Identical reference numerals refer to identical components. Additionally, in the drawings, the thicknesses, proportions, and dimensions of components are exaggerated for effective description.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

Terms such as first, second, and the like may be used to describe various components, but the components should not be limited by the terms. The terms may be used only for distinguishing one component from other components. For example, without departing the scope of the disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described with reference to the accompanying drawings.

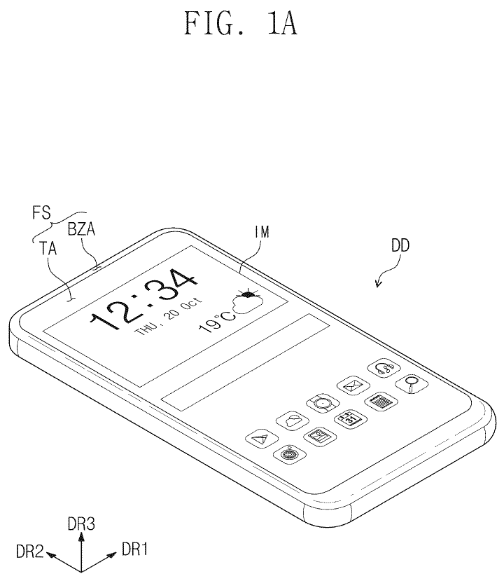

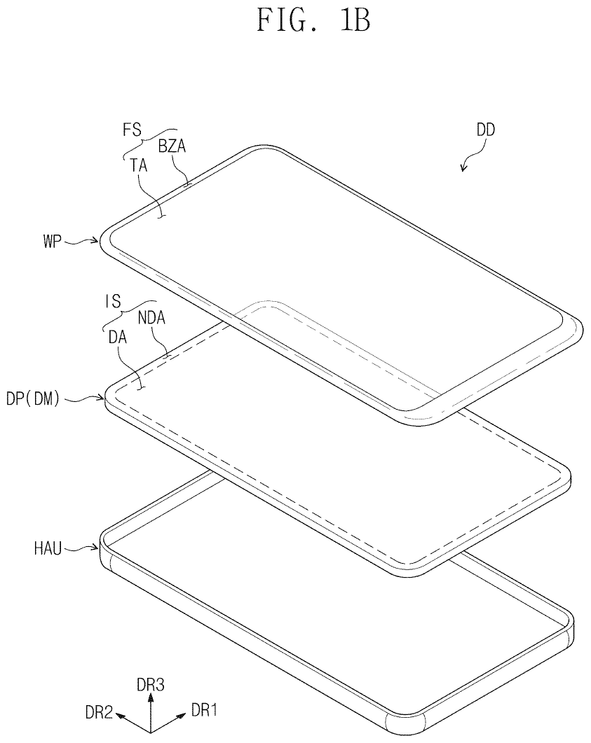

FIG. 1A is a perspective view of a display device DD according to an embodiment of the disclosure. FIG. 1B is an exploded perspective view of the display device DD according to the embodiment of the disclosure.

In an embodiment, the display device DD may be a large electronic device such as a television, a monitor, or a billboard. In addition, the display device DD may be a small and medium-sized electronic device such as a personal computer, a notebook computer, a personal digital terminal, a car navigation unit, a game machine, a smart phone, a tablet computer, or a camera. However, this is illustrative, and the display device DD may be employed as other display devices without departing from the spirit and scope of the disclosure. In FIGS. 1A and 1B, an embodiment where the display device DD is a smart phone is illustrated as an example.

Referring to FIGS. 1A and 1B, the display device DD may display an image IM in a third direction DR3 on a display surface FS that is parallel to a first direction DR1 and a second direction DR2. The image IM may include a still image as well as a dynamic image. In FIG. 1A, an embodiment where the image IM includes a clock window and icons is illustrated as an example. The display surface FS on which the image IM is displayed may correspond to a front surface of the display device DD.

In an embodiment, front surfaces (or, upper surfaces) and rear surfaces (or, lower surfaces) of members are defined based on the direction in which the image IM is displayed. The front surfaces and the rear surfaces may face away from each other in the third direction DR3 or in a thickness direction, and normal directions of the front surfaces and the rear surfaces may be parallel to the third direction DR3. Here, the directions indicated by the first to third directions DR1, DR2, and DR3 may be relative concepts and may be changed to different directions. As used herein, the expression “on a plane” or “in a plan view” may mean when viewed in the third direction DR3.

In an embodiment, as shown in FIG. 1B, the display device DD may include a window WP, a display module DM, and a housing HAU. The window WP and the housing HAU may be coupled with each other to form an exterior of the display device DD.

The window WP may include an optically clear insulating material. In an embodiment, for example, the window WP may include glass or plastic. A front surface of the window WP defines the display surface FS of the display device DD. The display surface FS may include a transmissive region TA and a bezel region BZA.

The transmissive region TA may be an optically clear region. In an embodiment, for example, the transmissive region TA may be a region having a visible light transmittance of about 90% or greater.

The bezel region BZA may be a region having a lower light transmittance than the transmissive region TA. The bezel region BZA may define the shape of the transmissive region TA. The bezel region BZA may be adjacent to the transmissive region TA and may surround the transmissive region TA. However, this is illustrative, and alternatively, the bezel region BZA of the window WP may be omitted. The window WP may include at least one selected from an anti-fingerprint layer, a hard coating layer, and an anti-reflection layer, but is not limited to any one embodiment.

The display module DM may be disposed under the window WP. The display module DM may include a display panel DP. The display module DM may be a component that substantially generates the image IM. The image IM generated by the display module DM may be displayed on a display surface IS of the display module DM and may be visually recognized by a user from the outside through the transmissive region TA.

The display module DM may include a display region DA and a non-display region NDA. The display region DA may be a region activated in response to an electrical signal. The non-display region NDA may be adjacent to the display region DA. The non-display region NDA may surround the display region DA. The non-display region NDA may be a region covered by the bezel region BZA and may not be visible from an outside.

The housing HAU may be coupled with the window WP. The housing HAU may be coupled with the window WP to provide a predetermined inner space. The display module DM may be accommodated in the inner space.

The housing HAU may include a material having a relatively high rigidity. In an embodiment, for example, the housing HAU may include glass, plastic, or metal, or may include a plurality of frames and/or plates including or formed of at least one selected from the aforementioned materials. The housing HAU may stably protect components of the display device DD accommodated in the inner space from an external impact.

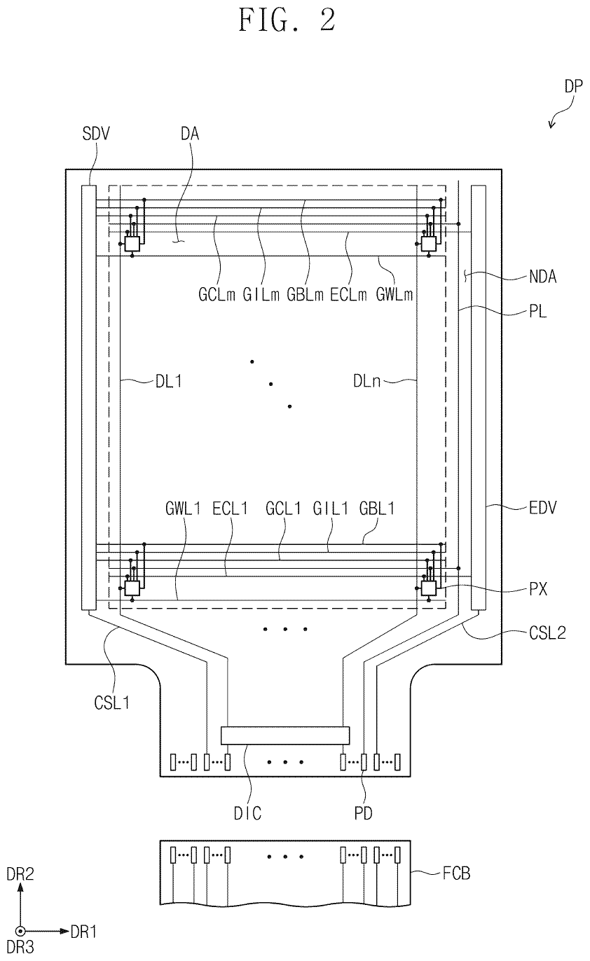

FIG. 2 is a plan view of a display panel DP according to an embodiment of the disclosure.

Referring to FIG. 2, in an embodiment, a display region DA and a non-display region NDA around the display region DA may be defined in the display panel DP. The display region DA and the non-display region NDA may be distinguished from each other depending on whether pixels PX are disposed. The pixels PX may be disposed in the display region DA. A scan driver SDV, a data driver, and an emission driver EDV may be disposed in the non-display region NDA. The data driver may be a circuit configured in a driver integrated circuit (IC) DIC.

The display panel DP may include the pixels PX, initialization scan lines GIL1 to GILm, compensation scan lines GCL1 to GCLm, write scan lines GWL1 to GWLm, black scan lines GBL1 to GBLm, emission control lines ECL1 to ECLm, data lines DL1 to DLn, first and second control lines CSL1 and CSL2, a drive voltage line PL, and a plurality of pads PD. Here, “m” and “n” are natural numbers of 2 or greater.

The pixels PX may be connected to the initialization scan lines GIL1 to GILm, the compensation scan lines GCL1 to GCLm, the write scan lines GWL1 to GWLm, the black scan lines GBL1 to GBLm, the emission control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in the first direction DR1 and may be electrically connected to the scan driver SDV. The data lines DL1 to DLn may extend in the second direction DR2 and may be electrically connected to the driver IC DIC. The emission control lines ECL1 to ECLm may extend in the first direction DR1 and may be electrically connected to the emission driver EDV.

The drive voltage line PL may include a portion extending in the first direction DR1 and a portion extending in the second portion DR2. The portion extending in the first direction DR1 and the portion extending in the second portion DR2 may be disposed in (or directly on) different layers from each other. The drive voltage line PL may provide a drive voltage to the pixels PL.

The first control line CSL1 may be connected to the scan driver SDV. The second control line CSL2 may be connected to the emission driver EDV.

The driver IC DIC, the drive voltage line PL, the first control line CSL1, and the second control line CSL2 may be electrically connected to the pads PD. A flexible circuit film FCB may be electrically connected to the pads PD through an anisotropic conductive adhesive layer. The pads PD may be pads for connecting the flexible circuit film FCB to the display panel DP. The pads PD may be connected to the corresponding pixels PX through the drive voltage line PL, the first control line CSL1, and the second control line CSL2.

In addition, the pads PD may further include input pads. The input pads may be pads for connecting the flexible circuit film FCB to an input sensor INS (refer to FIG. 2). However, without being limited thereto, the input pads may be disposed in the input sensor INS and may be connected with the pads PD and a separate circuit board. Alternatively, the input sensor INS may be omitted, and the input pads may not be further included.

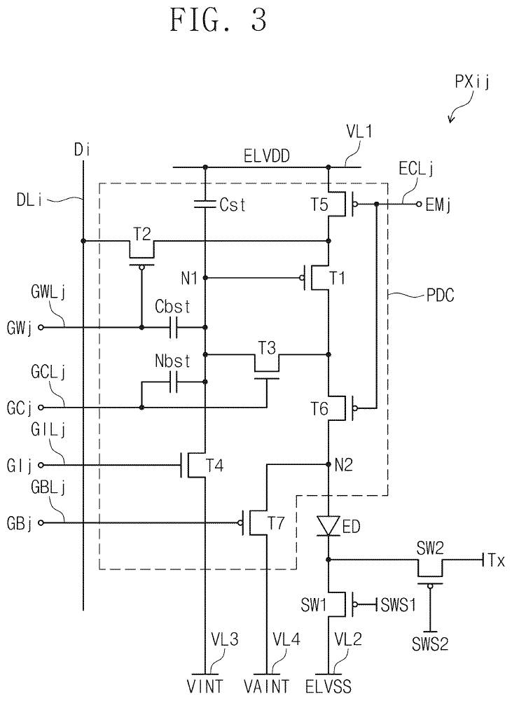

FIG. 3 is an equivalent circuit diagram of a pixel PXij according to an embodiment of the disclosure.

FIG. 3 illustrates the equivalent circuit diagram of the pixel PXij among the plurality of pixels PX (refer to FIG. 2). The plurality of pixels PX have a same circuit structure as each other. Therefore, description of the circuit structure for the pixel PXij may be applied to the remaining pixels PX, and any repetitive detailed description of the remaining pixels PX will be omitted.

Referring to FIGS. 2 and 3, an embodiment of the pixel PXij is connected to an i-th data line DLi among the data lines DL1 to DLn, the j-th initialization scan line GILj among the initialization scan lines GIL1 to GILm, a j-th compensation scan line GCLj among the compensation scan lines GIL1 to GILm, a j-th write scan line GWLj among the write scan lines GWL1 to GWLm, a j-th black scan line GBLj among the black scan lines GBL1 to GBLm, a j-th emission control line ECLj among the emission control lines ECL1 to ECLm, first and second drive voltage lines VL1 and VL2, and first and second initialization voltage lines VL3 and VL4. Here, “i” is an integer of 1 to n, and “j” is an integer of 1 to m.

The pixel PXij includes a light emitting element ED and a pixel circuit PDC. The light emitting element ED may be a light emitting diode. In an embodiment of the disclosure, the light emitting element ED may be an organic light emitting diode including an organic light emitting layer, but is not particularly limited thereto. The pixel circuit PDC may control the amount of current flowing through the light emitting element ED based on a data signal Di. The light emitting element ED may emit light having a predetermined luminance corresponding to the amount of current provided from the pixel circuit PDC.

The pixel circuit PDC may include first to seventh transistors T1, T2, T3, T4, T5, T6, and T7 and first to third capacitors Cst, Cbst, and Nbst. A configuration of the pixel circuit PDC according to the disclosure is not limited to the embodiment illustrated in FIG. 3. The pixel circuit PDC illustrated in FIG. 3 is merely illustrative, and various changes and modifications can be made to the configuration of the pixel circuit PDC.

At least one selected from the first to seventh transistors T1, T2, T3, T4, T5, T6, and T7 may be a transistor having a low-temperature polycrystalline silicon (LTPS) semiconductor layer. At least one selected from the first to seventh transistors T1, T2, T3, T4, T5, T6, and T7 may be a transistor having an oxide semiconductor layer. In an embodiment, for example, the third and fourth transistors T3 and T4 may be oxide semiconductor transistors, and the first, second, fifth, sixth, and seventh transistors T1, T2, T5, T6, and T7 may be LTPS transistors.

In an embodiment, the first transistor T1 directly affecting the brightness of the light emitting element ED may include a semiconductor layer including or formed of polycrystalline silicon having high reliability, and thus the display device having a high resolution may be implemented. An oxide semiconductor has high carrier mobility and low leakage current, and therefore a voltage drop is not great even though operating time is long. That is, the color of an image is not greatly changed depending on a voltage drop even during a low-frequency operation, and therefore the low-frequency operation is possible. In an embodiment, since the oxide semiconductor has a desired characteristics of low leakage current as described above, at least one selected from the third transistor T3, which is connected with a gate electrode of the first transistor T1, and the fourth transistor T4 may be employed as an oxide semiconductor to reduce power consumption while preventing leakage current that is likely to flow to the gate electrode.

Some of the first to seventh transistors T1, T2, T3, T4, T5, T6, and T7 may be P-type transistors, and the others may be N-type transistors. In an embodiment, for example, the first, second, fifth, sixth, and seventh transistors T1, T2, T5, T6, and T7 may be P-type transistors, and the third and fourth transistors T3 and T4 may be N-type transistors.

A configuration of the pixel circuit PDC according to an embodiment of the disclosure is not limited to the embodiment illustrated in FIG. 3. The pixel circuit PDC illustrated in FIG. 3 is merely illustrative, and various changes and modifications can be made to the configuration of the pixel circuit PDC. In an alternative embodiment, for example, the first to seventh transistors T1, T2, T3, T4, T5, T6, and T7 may all be P-type transistors or N-type transistors. Alternatively, the first, second, fifth, and sixth transistors T1, T2, T5, and T6 may be P-type transistors, and the third, fourth, and seventh transistors T3, T4, and T7 may be N-type transistors.

The j-th initialization scan line GILj, the j-th compensation scan line GCLj, the j-th write scan line GWLj, the j-th black scan line GBLj, and the j-th emission control line ECLj may transfer the j-th initialization scan signal GIj, the j-th compensation scan signal GCj, the j-th write scan signal GWj, the j-th black scan signal GBj, and the j-th emission control signal EMj to the pixel PXij, respectively. The i-th data line DLi transfers the i-th data signal Di to the pixel PXij. The i-th data signal Di may have a voltage level corresponding to an image signal that is input to the display device DD (refer to FIG. 1).

The first drive voltage line VL1 may transfer a first drive voltage ELVDD to the pixel PXij, and the second drive voltage line VL2 may transfer a second drive voltage ELVSS to the pixel PXij.

In an embodiment, a first switch SW1 and a second switch SW2 may be connected to the light emitting element ED. Although FIG. 3 illustrates one an embodiment where the first switch SW1 and the second switch SW2 are P-type transistors, the disclosure is not particularly limited thereto. The first switch SW1 may be connected between the second drive voltage line VL2 and the light emitting element ED.

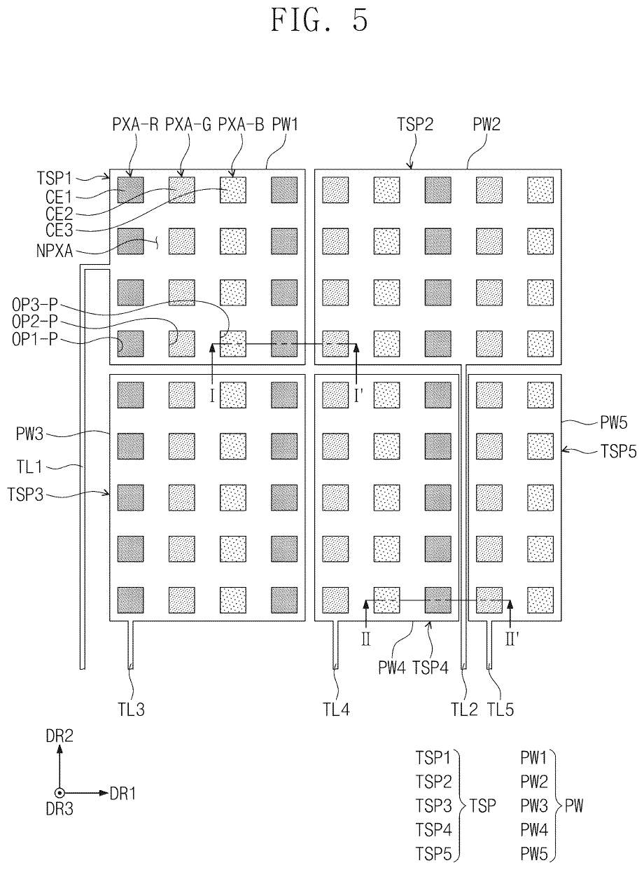

The first switch SW1 may be controlled by a first switch signal SWS1, and the second switch SW2 may be controlled by a second switch signal SWS2. Signals provided to touch electrodes TSP (refer to FIG. 5) may be controlled by controlling the on/off of the first switch SW1 and the second switch SW2. In an embodiment, for example, when the first switch SW1 is turned on and the second switch SW2 is turned off, the second drive voltage ELVSS may be provided to the touch electrodes TSP, and this may be referred to as a first mode. When the first switch SW1 is turned off and the second switch SW2 is turned on, a touch sensing signal Tx may be provided to the touch electrodes TSP, and this may be referred to as a second mode. The first mode and the second mode may be alternately operated. In an embodiment, for example, the first mode and the second mode may be alternately operated in a time-division manner.

In an embodiment, the first and second initialization voltage lines VL3 and VL4 may transfer a first initialization voltage VINT and a second initialization voltage VAINT to the pixel PXij, respectively.

The first transistor T1 is connected between the first drive voltage line VL1 that receives the first drive voltage ELVDD and the light emitting element ED. The first transistor T1 includes a first electrode connected with the first drive voltage line VL1 via the fifth transistor T5, a second electrode connected with a pixel electrode (or, referred to as an anode) of the light emitting element ED via the sixth transistor T6, and a third electrode (e.g., a gate electrode) connected with one end of the first capacitor Cst (e.g., a first node N1). The first transistor T1 may receive the i-th data signal Di that the i-th data line DLi transfers based on a switching operation of the second transistor T2 and may supply a drive current to the light emitting element ED.

The second transistor T2 is connected between the i-th data line DLi and the first electrode of the first transistor T1. The second transistor T2 includes a first electrode connected with the i-th data line DLi, a second electrode connected with the first electrode of the first transistor T1, and a third electrode (e.g., a gate electrode) connected with the j-th write scan line GWLj. The second transistor T2 may be turned on in response to the j-th write scan signal GWj transferred through the j-th write scan line GWLj and may transfer, to the first electrode of the first transistor T1, the i-th data signal Di transferred from the i-th data line DLi. One end of the second capacitor Cbst may be connected to the third electrode of the second transistor T2, and an opposite end of the second capacitor Cbst may be connected to the first node N1.

The third transistor T3 is connected between the second electrode of the first transistor T1 and the first node N1. The third transistor T3 includes a first electrode connected with the third electrode of the first transistor T1, a second electrode connected with the second electrode of the first transistor T1, and a third electrode (e.g., a gate electrode) connected with the j-th compensation scan line GCLj. The third transistor T3 may be turned on in response to the j-th compensation scan signal GCj transferred through the j-th compensation scan line GCLj and may diode-connect the first transistor T1 by connecting the third electrode of the first transistor T1 and the second electrode of the first transistor T1. One end of the third capacitor Nbst may be connected to the third electrode of the third transistor T3, and an opposite end of the third capacitor Nbst may be connected to the first node N1.

The fourth transistor T4 is connected between the first initialization voltage line VL3 through which the first initialization voltage VINT is applied and the first node N1. The fourth transistor T4 includes a first electrode connected with the first initialization voltage line VL3 through which the first initialization voltage VINT is transferred, a second electrode connected with the first node N1, and a third electrode (e.g., a gate electrode) connected with the j-th initialization scan line GILj. The fourth transistor T4 is turned on in response to the j-th initialization scan signal GIj transferred through the j-th initialization scan line GILj. The turned-on fourth transistor T4 initializes the potential of the third electrode of the first transistor T1 (that is, the potential of the first node N1) by transferring the first initialization voltage VINT to the first node N1.

The fifth transistor T5 includes a first electrode connected with the first drive voltage line VL1, a second electrode connected with the first electrode of the first transistor T1, and a third electrode (e.g., a gate electrode) connected to the j-th emission control line ECLj. The sixth transistor T6 includes a first electrode connected with the second electrode of the first transistor T1, a second electrode connected to the pixel electrode of the light emitting element ED, and a third electrode (e.g., a gate electrode) connected to the j-th emission control line ECLj.

The fifth and sixth transistors T5 and T6 are simultaneously turned on in response to the j-th emission control signal EMj transferred through the j-th emission control line ECLj. The first drive voltage ELVDD applied through the turned-on fifth transistor T5 may be compensated for through the diode-connected first transistor T1 and thereafter may be transferred to the light emitting element ED through the sixth transistor T6.

The seventh transistor T7 includes a first electrode connected to the second initialization voltage line VL4 through which the second initialization voltage VAINT is transferred, a second electrode connected with the second electrode of the sixth transistor T6, and a third electrode (e.g., a gate electrode) connected with the j-th black scan line GBLj. The second initialization voltage VAINT may have a voltage level lower than or equal to the voltage level of the first initialization voltage VINT.

The one end of the first capacitor Cst is connected with the third electrode of the first transistor T1, and an opposite end of the first capacitor Cst is connected with the first drive voltage line VL1. A cathode of the light emitting element ED may be connected with the second drive voltage line VL2 that transfers the second drive voltage ELVSS. The second drive voltage ELVSS may have a lower voltage level than the first drive voltage ELVDD.

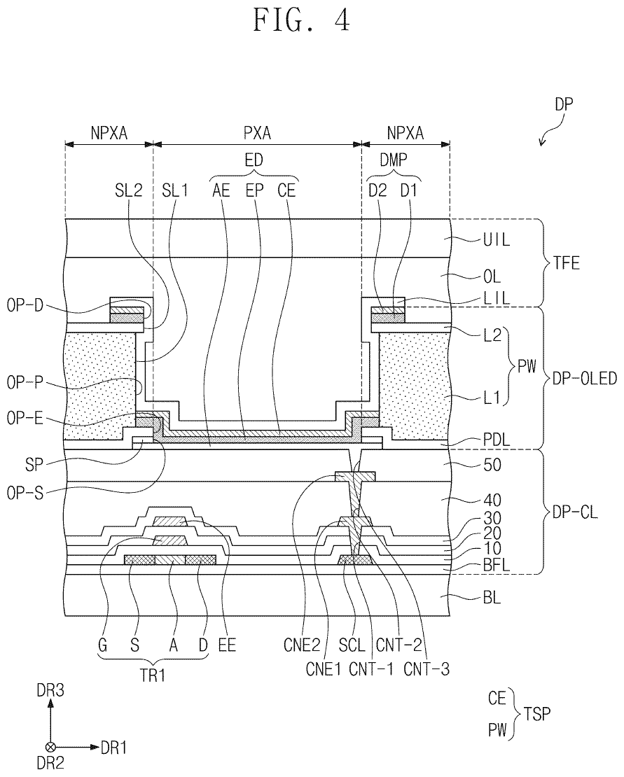

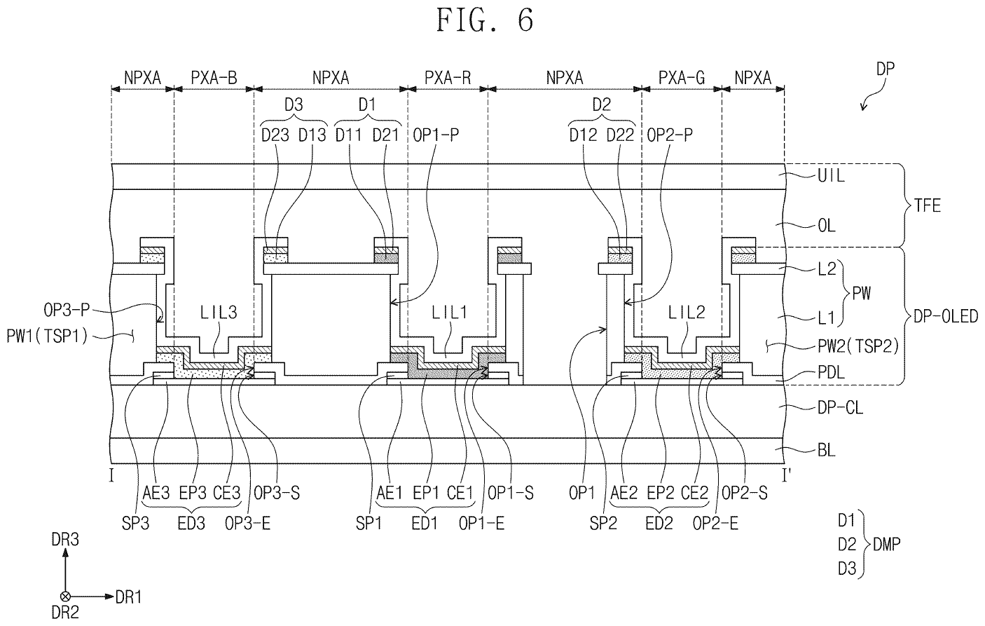

FIG. 4 is a sectional view of the display panel according to an embodiment of the disclosure. FIG. 4 illustrates an enlarged view of a portion corresponding to one emissive region PXA in the display region DA (refer to FIG. 1B). The emissive region PXA of FIG. 4 may correspond to one of first to third emissive regions PXA-R, PXA-G, and PXA-B, and a light emitting element ED of FIG. 4 may correspond to one of first to third light emitting elements ED1, ED2, and ED3 of FIG. 6.

Referring to FIG. 4, an embodiment of the display panel DP may be an emissive display panel. However, this is illustrative, and the disclosure is not particularly limited thereto. In an embodiment, for example, the display panel DP may be an organic light emitting display panel or an inorganic light emitting display panel. An emissive layer in the organic light emitting display panel may include an organic light emitting material. An emissive layer in the inorganic light emitting display panel may include quantum dots, quantum rods, or micro light emitting diodes (LEDs). Hereinafter, for convenience of description, embodiments where the display panel DP is an organic light emitting display panel will be described in detail, but not being limited thereto.

The display panel DP may include a base layer BL, a circuit layer DP-CL, a display element layer DP-OLED, and a thin film encapsulation layer TFE. As used herein, the expression “component A is directly disposed on component B” may mean that an adhesive layer is not disposed between component A and component B by directly forming component A on component B.

The base layer BL may include at least one plastic film. The base layer BL may be a flexible substrate and may include a plastic substrate, a glass substrate, a metal substrate, or an organic/inorganic composite substrate. The display region DA and the non-display region NDA described above with reference to FIG. 1B may be identically defined in the base layer BL.

The display layer DP may include a plurality of insulating layers, a semiconductor pattern, a conductive pattern, and a signal line. An insulating layer, a semiconductor layer, and a conductive layer are formed by coating, deposition, or the like. Thereafter, the insulating layer, the semiconductor layer, and the conductive layer may be selectively subjected to patterning by photolithography and etching. The semiconductor pattern, the conductive pattern, and the signal line included in the circuit layer DP-CL and the display element layer DP-OLED may be formed by the above-described method.

The circuit layer DP-CL may be disposed on the base layer BL. The circuit layer DP-CL may include a buffer layer BFL, a transistor TRI, a signal transmission region SCL, first to fifth insulating layers 10, 20, 30, 40, and 50, an electrode EE, and a plurality of connecting electrodes CNE1 and CNE2.

The buffer layer BFL may be disposed on the base layer BL. The buffer layer BFL may improve a bonding force between the base layer BL and a semiconductor pattern. In an embodiment, the buffer layer BFL may include silicon oxide layers and silicon nitride layers. In such an embodiment, the silicon oxide layers and the silicon nitride layers may be alternately stacked one above another.

The semiconductor pattern may be disposed on the buffer layer BFL. In an embodiment, the semiconductor pattern may include poly-silicon. Alternatively, without being limited thereto, the semiconductor pattern may include amorphous silicon or metal oxide. In FIG. 4, a portion of the semiconductor pattern is illustrated as an example, and the semiconductor pattern may be further disposed in the plurality of emissive regions PXA-R, PXA-G, PXA-B (refer to FIG. 5). The semiconductor pattern may be arranged across the plurality of emissive regions PXA-R, PXA-G, PXA-B according to a specific rule. The semiconductor pattern may have different electrical properties depending on whether the semiconductor pattern is doped or not. The semiconductor pattern may include a first region having a high doping concentration and a second region having a low doping concentration. The first region may be doped with an N-type dopant or a P-type dopant. A P-type transistor may include a first region doped with a P-type dopant.

The first region may have a higher conductivity than the second region and may substantially serve as an electrode or a signal line. The second region may substantially correspond to an active (or, channel) region of the transistor. In such an embodiment, one portion of the semiconductor pattern may be the active region of the transistor, another portion may be a source or drain of the transistor, and another portion may be a conductive region.

A source S, an active region A, and a drain D of the transistor TRI may be formed from the semiconductor pattern. FIG. 4 illustrates a portion of the signal transmission region SCL formed from (or defined by a portion of) the semiconductor pattern. Although not separately illustrated, the signal transmission region SCL may be connected to the drain D of the transistor TRI on a plane (or in a plan view).

The first to fifth insulating layers 10, 20, 30, 40, and 50 may be disposed on the buffer layer BFL. The first to fifth insulating layers 10, 20, 30, 40, and 50 may be inorganic layers or organic layers.

The first insulating layer 10 may be disposed on the buffer layer BFL. The first insulating layer 10 may cover the source S, the active region A, and the drain D of the transistor TRI and the signal transmission region SCL that are disposed on the buffer layer BFL. A gate G of the transistor TRI may be disposed on the first insulating layer 10. The second insulating layer 20 may be disposed on the first insulating layer 10 and may cover the gate G. The electrode EE may be disposed on the second insulating layer 20. The third insulating layer 30 may be disposed on the second insulating layer 20 and may cover the electrode EE.

The first connecting electrode CNE1 may be disposed on the third insulating layer 30. The first connecting electrode CNE1 may be connected to the signal transmission region SCL through a contact hole CNT-1 defined through the first to third insulating layers 10, 20, and 30. The fourth insulating layer 40 may be disposed on the third insulating layer 30 and may cover the first connecting electrode CNE1. The fourth insulating layer 40 may be an organic layer.

The second connecting electrode CNE2 may be disposed on the fourth insulating layer 40. The second connecting electrode CNE2 may be connected to the first connecting electrode CNE1 through a contact hole CNT-2 defined through the fourth insulating layer 40. The fifth insulating layer 50 may be disposed on the fourth insulating layer 40 and may cover the second connecting electrode CNE2. The fifth insulating layer 50 may be an organic layer.

The display element layer DP-OLED may be disposed on the circuit layer DP-CL. The display element layer DP-OLED may include the light emitting element ED, a sacrificial pattern SP, a pixel defining layer PDL, a barrier wall PW, and dummy patterns DMP.

The light emitting element ED may include an anode AE (or, a first electrode), an emission pattern EP, and a cathode CE (or, a second electrode). Each of the first to third light emitting elements ED1, ED2, and ED3 to be described below may include substantially the same configuration as the light emitting element ED of FIG. 4. Descriptions (or The above-described features) of the anode AE, the emission pattern EP, and the cathode CE may be identically applied to an anode, an emission pattern, and a cathode of each of the first to third light emitting elements ED1, ED2, and ED3 to be described below.

The anode AE may be disposed on the fifth insulating layer 50 of the circuit layer DP-CL. The anode AE may be a transparent electrode, a translucent electrode, or a reflective electrode. The anode AE may be connected to the second connecting electrode CNE2 by a connection contact hole CNT-3 defined through the fifth insulating layer 50. Accordingly, the anode AE may be electrically connected to the signal transmission region SCL through the first and second connecting electrodes CNE1 and CNE2 and may be electrically connected to a corresponding circuit element. The anode AE may have a single-layer structure or a multi-layer structure. The anode AE may include a plurality of layers including ITO and Ag. In an embodiment, for example, the anode AE may include a layer including ITO (hereinafter, referred to as the lower IOT layer), a layer disposed on the lower IOT layer and including Ag (hereinafter, referred to as the Ag layer), and a layer disposed on the Ag layer and including ITO (hereinafter, referred to as the upper ITO layer).

The sacrificial pattern SP may be disposed between the anode AE and the pixel defining layer PDL. A sacrificial opening OP-S that exposes a portion of an upper surface of the anode AE may be defined in the sacrificial pattern SP. The sacrificial opening OP-S may overlap a light emitting opening OP-E to be described below. The sacrificial pattern SP may include amorphous transparent conductive oxide. The sacrificial pattern SP may include an aluminum zinc oxide (AZO) compound. In an embodiment, for example, the sacrificial pattern SP may be zinc oxide ZnOₓ doped with aluminum (Al). In such an embodiment, the aluminum (Al) content may be in a range from 2 atomic percent (at %) to 5 at %.

The pixel defining layer PDL may be disposed on the fifth insulating layer 50 of the circuit layer DP-CL. The light emitting opening OP-E may be defined in the pixel defining layer PDL. The light emitting opening OP-E may correspond to the anode AE, and the pixel defining layer PDL may expose at least a portion of the anode AE through the light emitting opening OP-E.

In an embodiment, the light emitting opening OP-E may correspond to the sacrificial opening OP-S of the sacrificial pattern SP. According to an embodiment, the upper surface of the anode AE may be spaced apart from the pixel defining layer PDL on the section with the sacrificial pattern SP therebetween. Accordingly, damage to the anode AE in a process of forming the light emitting opening OP-E may be effectively prevented.

In an embodiment, on the plane, an inner surface of the sacrificial pattern SP that defines the sacrificial opening OP-S may be substantially aligned with an inner surface of the pixel defining layer PDL that defines the corresponding light emitting opening OP-E. In such an embodiment, the emissive region PXA may be a region of the anode AE exposed through the sacrificial opening OP-S. However, this is illustrative, and the disclosure is not limited thereto. In an embodiment, for example, on the plane, the area of the light emitting opening OP-E may be smaller than the area of the sacrificial opening OP-S. That is, the inner surface of the pixel defining layer PDL that defines the light emitting opening OP-E may be closer to the center of the anode AE than the inner surface of the sacrificial pattern SP that defines the sacrificial opening OP-S.

The pixel defining layer PDL may include an inorganic insulating material. In an embodiment, for example, the pixel defining layer PDL may include silicon nitride SiNₓ. The pixel defining layer PDL may be disposed between the anode AE and the barrier wall PW and may block electrical connection between the anode AE and the barrier wall PW.

The barrier wall PW may be disposed on the pixel defining layer PDL. A barrier opening OP-P may be defined in the barrier wall PW. The barrier opening OP-P may correspond to the light emitting opening OP-E and may expose at least a portion of the anode AE.

The barrier wall PW may have an undercut shape on the section. The barrier wall PW may include multiple layers sequentially stacked one above another, and at least one layer among the multiple layers may be relatively recessed, compared to the other layers. Accordingly, the barrier wall PW may include a tip portion.

The barrier wall PW may include a first barrier wall layer L1 and a second barrier wall layer L2. Based on the emissive region PXA, the first barrier wall layer L1 may be relatively recessed, compared to the second barrier wall layer L2. That is, the first barrier wall layer L1 may be undercut with respect to the second barrier wall layer L2.

The barrier opening OP-P defined in the barrier wall PW may include a first region and a second region. The first barrier wall layer L1 may include a first inner surface SL1 that defines the first region of the barrier opening OP-P, and the second barrier wall layer L2 may include a second inner surface SL2 that defines the second region of the barrier opening OP-P. The first inner surface SL1 may be relatively recessed inward, compared to the second inner surface SL2. The second barrier wall layer L2 protruding toward a center of the emissive region PXA may define the tip portion.

The first barrier wall layer L1 may be disposed on the pixel defining layer PDL, and the second barrier wall layer L2 may be disposed on the first barrier wall layer L1. The first barrier wall layer L1 may have a first conductivity and a first thickness, and the second barrier wall layer L2 may have a second conductivity and a second thickness. The first conductivity may be higher than the second conductivity, and the first thickness may be greater than the second thickness.

Although FIG. 4 illustrates an embodiment where the first inner surface SL1 and the second inner surface SL2 are perpendicular to an upper surface of the pixel defining layer PDL, the disclosure is not limited thereto. In alternative an embodiment, for example, the barrier wall PW may have a tapered shape or an inverted tapered shape.

The emission pattern EP may be disposed on the anode AE. The emission pattern EP may include an emissive layer including a luminescent material. The emission pattern EP may further include a hole injection layer (HIL) and a hole transport layer (HTL) that are disposed between the anode AE and the emissive layer and may further include an electron transport layer (ETL) and an electron injection layer (EIL) that are disposed on the emissive layer. The emission pattern EP may be referred to as an organic layer or an intermediate layer.

The emission pattern EP may be patterned by the tip portion defined on the barrier wall PW. The emission pattern EP may be disposed in the sacrificial opening OP-S, the light emitting opening OP-E, and the barrier opening OP-P. The emission pattern EP may cover a portion of the upper surface of the pixel defining layer PDL exposed through the barrier opening OP-P.

The cathode CE may be disposed on the emission pattern EP. The cathode CE may be patterned by the tip portion defined on the barrier wall PW. The cathode CE may contact the first inner surface SL1 of the first barrier wall layer L1.

The barrier wall PW may receive the second drive voltage ELVSS (refer to FIG. 3). Accordingly, the cathode CE may be electrically connected to the barrier wall PW and may receive the second drive voltage ELVSS.

Although FIG. 4 illustrates an embodiment where the emission pattern EP and the cathode CE contact the first inner surface SL1 of the first barrier wall layer L1, the disclosure is not limited thereto. In an alternative embodiment, for example, the emission pattern EP may not contact the first inner surface SL1 of the first barrier wall layer L1.

According to an embodiment of the disclosure, the display panel DP may further include a capping pattern (not illustrated). The capping pattern may be disposed in the barrier opening OP-P and may be disposed on the cathode CE. The capping pattern may be patterned by the tip portion formed on the barrier wall PW.

The dummy patterns DMP may be disposed on the barrier wall PW. The dummy patterns MP may include a first dummy pattern D1 and a second dummy pattern D2. The first dummy pattern D1 and the second dummy pattern D2 may be sequentially stacked on an upper surface of the second barrier wall layer L2 of the barrier wall PW in the third direction DR3.

The first dummy pattern D1 may include an organic material. In an embodiment, for example, the first dummy pattern D1 may include a same material as the emission pattern EP. The first dummy pattern D1 may be simultaneously formed with the emission pattern EP through a same process and may be separated from the emission pattern EP by the undercut shape of the barrier wall PW.

The second dummy pattern D2 may include a conductive material. In an embodiment, for example, the second dummy pattern D2 may include a same material as the cathode CE. The second dummy pattern D2 may be simultaneously formed with the cathode CE through a same process and may be separated from the cathode CE by the undercut shape of the barrier wall PW.

According to an embodiment of the disclosure in which the display panel DP further includes the capping pattern, the dummy patterns DMP may further include a third dummy pattern (not illustrated). The third dummy pattern may be disposed on the second dummy pattern D2. The third dummy pattern may include a same material as the capping pattern. The third dummy pattern may be simultaneously formed with the capping pattern through a same process and may be separated from the capping pattern by the undercut shape of the barrier wall PW.

A dummy opening OP-D may be defined in the dummy patterns DMP. The dummy opening OP-D may correspond to the light emitting opening OP-E. The dummy opening OP-D may include a first region and a second region sequentially arranged in the third direction DR3. The first region of the dummy opening OP-D may be defined by an inner surface of the first dummy pattern D1, and the second region of the dummy opening OP-D may be defined by an inner surface of the second dummy pattern D2. On the plane, each of the first dummy pattern D1 and the second dummy pattern D2 may have a closed-line shape surrounding the emissive region PXA.

Although FIG. 4 illustrates an embodiment where the inner surfaces of the first dummy pattern D1 and the second dummy pattern D2 are aligned with the second inner surface SL2 of the second barrier wall layer L2, the disclosure is not limited thereto, and alternatively, the first dummy pattern D1 and the second dummy pattern D2 may cover the second inner surface SL2 of the second barrier wall layer L2.

The thin film encapsulation layer TFE may be disposed on the display element layer DP-OLED. The thin film encapsulation layer TFE may include a lower inorganic encapsulation pattern LIL, an organic encapsulation film OL, and an upper inorganic encapsulation film UIL.

The lower inorganic encapsulation pattern LIL may correspond to the light emitting opening OP-E. The lower inorganic encapsulation pattern LIL may cover the light emitting element ED and the dummy patterns DMP, and a portion of the lower inorganic encapsulation pattern LIL may be disposed in the barrier opening OP-P. According to an embodiment, the lower inorganic encapsulation pattern LIL may be brought into contact with the first inner surface SL1 of the first barrier wall layer L1.

The organic encapsulation film OL may cover the lower inorganic encapsulation pattern LIL and may provide a flat upper surface. The upper inorganic encapsulation film UIL may be disposed on the organic encapsulation film OL.

The lower inorganic encapsulation pattern LIL and the upper inorganic encapsulation film UIL may protect the display element layer DP-OLED from moisture/oxygen, and the organic encapsulation film OL may protect the display element layer DP-OLED from foreign matter such as dust particles.

FIG. 5 is a plan view illustrating the plurality of touch electrodes TSP of the display panel DP (refer to FIG. 1B) according to an embodiment of the disclosure. The first to third emissive regions PXA-R, PXA-G, and PXA-B and a peripheral region NPXA surrounding the first to third emissive regions PXA-R, PXA-G, and PXA-B are illustrated in FIG. 5.

Referring to FIG. 5, in an embodiment, the first to third emissive regions PXA-R, PXA-G, and PXA-B may overlap first to third barrier openings OP1-P, OP2-P, and OP3-P, and the peripheral region NPXA may overlap a plurality of barrier wall patterns PW1, PW2, PW3, PW4, and PW5 to be described below and a separation space between the plurality of touch electrodes TSP.

The first to third emissive regions PXA-R, PXA-G, and PXA-B may be regions through which light provided from the light emitting elements ED1, ED2, and ED3 (refer to FIG. 6) is emitted. The first to third emissive regions PXA-R, PXA-G, and PXA-B may be distinguished from one another depending on the colors of lights emitted toward the outside of the display module DM (refer to FIG. 1B). The first to third emissive regions PXA-R, PXA-G, and PXA-B may provide first to third color lights having different colors. In an embodiment, for example, the first color light may be red light, the second color light may be green light, and the third color light may be blue light. However, examples of the first to third color lights are not necessarily limited thereto.

Each of the first to third emissive regions PXA-R, PXA-G, and PXA-B may be defined as a region where an upper surface of an anode is exposed by a light emitting opening to be described below. The peripheral region NPXA may set the boundaries between the first to third emissive regions PXA-R, PXA-G, and PXA-B and may prevent color mixing between the first to third emissive regions PXA-R, PXA-G, and PXA-B.

In an embodiment, the shapes, areas, and arrangement of the first to third emissive regions PXA-R, PXA-G, and PXA-B of the display module DM (refer to FIG. 1B) of the disclosure may be variously designed depending on the colors of emitted lights or the size and configuration of the display module DM.

A plurality of first emissive regions PXA-R, a plurality of second emissive regions PXA-G, and a plurality of third emissive regions PXA-B may be provided. The plurality of first emissive regions PXA-R, the plurality of second emissive regions PXA-G, and the plurality of third emissive regions PXA-B may have a predetermined arrangement in the display region DA (refer to FIG. 2) and may be repeatedly disposed. FIG. 5 exemplarily illustrates an embodiment in which the first to third emissive regions PXA-R, PXA-G, and PXA-B are arranged in one direction. However, without being limited thereto, the first to third emissive regions PXA-R, PXA-G, and PXA-B may be arranged in various forms. In an embodiment, the first to third emissive regions PXA-R, PXA-G, and PXA-B may have a PENTILE™ arrangement, a stripe arrangement, or a Diamond Pixel™ arrangement.

FIG. 5 illustrates an embodiment where the first to third emissive regions PXA-R, PXA-G, and PXA-B have a quadrangular shape. However, without being limited thereto, the first to third emissive regions PXA-R, PXA-G, and PXA-B may have various shapes on the plane. In an embodiment, for example, the first to third emissive regions PXA-R, PXA-G, and PXA-B may have a polygonal, circular, or oval shape. The first to third emissive regions PXA-R, PXA-G, and PXA-B may have a same shape as each other on the plane, or at least some of the first to third emissive regions PXA-R, PXA-G, and PXA-B may have different shapes from each other on the plane.

FIG. 5 illustrates an embodiment where the first to third emissive regions PXA-R, PXA-G, and PXA-B have a same size or area (e.g., a planer area) as each other. However, without being limited thereto, the first to third emissive regions PXA-R, PXA-G, and PXA-B may have various areas depending on the design of the display module DM (refer to FIG. 1B). In an embodiment, for example, at least some of the first to third emissive regions PXA-R, PXA-G, and PXA-B may have different areas from each other on the plane. In an embodiment, the area of the first emissive region PXA-R that emits red light may be greater than the area of the second emissive region PXA-G that emits green light and smaller than the area of the third emissive region PXA-B that emits blue light.

Cathodes CE1, CE2, and CE3 corresponding to the first to third emissive regions PXA-R, PXA-G, and PXA-B may be disposed in the first to third emissive regions PXA-R, PXA-G, and PXA-B. In an embodiment, the first cathode CE1 may be disposed in the first emissive region PXA-R, the second cathode CE2 may be disposed in the second emissive region PXA-G, and the third cathode CE3 may be disposed in the third emissive region PXA-B.

The display panel DP (refer to FIG. 1B) may include the plurality of touch electrodes TSP. The plurality of touch electrodes TSP may be disposed between the circuit layer DP-CL (refer to FIG. 4) and the thin film encapsulation layer TFE (refer to FIG. 4). The plurality of touch electrodes TSP may include first to fifth touch electrodes TSP1, TSP2, TSP3, TSP4, and TSP5. The first to fifth touch electrodes TSP1, TSP2, TSP3, TSP4, and TSP5 may be spaced apart from each other. The plurality of touch electrodes TSP may be referred to as an electrode layer TSP.

According to an embodiment of the disclosure, since the display device DD (refer to FIG. 1A) includes the plurality of touch electrodes TSP disposed between the circuit layer DP-CL and the thin film encapsulation layer TFE rather than disposed in a separate input sensing layer, the weight or thickness of the display device DD may be decreased.

The barrier wall PW may include the plurality of barrier wall patterns PW1, PW2, PW3, PW4, and PW5. The plurality of barrier wall patterns PW1, PW2, PW3, PW4, and PW5 may be spaced apart from each other. The first to third barrier openings OP1-P, OP2-P, and OP3-P corresponding to the first to third emissive regions PXA-R, PXA-G, and PXA-G may be defined or formed by each of the plurality of barrier wall patterns PW1, PW2, PW3, PW4, and PW5.

Each of the plurality of touch electrodes TSP may include a corresponding barrier wall pattern among the plurality of barrier wall patterns PW1, PW2, PW3, PW4, and PW5 and may include some corresponding cathodes among the plurality of cathodes CE1, CE2, and CE3. In an embodiment, for example, the first touch electrode TSPI may include the first barrier wall pattern PW1 and some of the first to third cathodes CE1, CE2, and CE3 corresponding to the first barrier wall pattern PW1, and the second touch electrode TSP2 may include the second barrier wall pattern PW2 and some of the first to third cathodes CE1, CE2, and CE3 corresponding to the second barrier wall pattern PW2. In such an embodiment, the third touch electrode TSP3 may include the third barrier wall pattern PW3 and some of the first to third cathodes CE1, CE2, and CE3 corresponding to the third barrier wall pattern PW3, the fourth touch electrode TSP4 may include the fourth barrier wall pattern PW4 and some of the first to third cathodes CE1, CE2, and CE3 corresponding to the fourth barrier wall pattern PW4, and the fifth touch electrode TSP5 may include the fifth barrier wall pattern PW5 and some of the first to third cathodes CE1, CE2, and CE3 corresponding to the fifth barrier wall pattern PW5.

The display panel DP may further include a plurality of trace lines TL1, TL2, TL3, TL4, and TL5 electrically connected with the plurality of touch electrodes TSP. The plurality of trace lines TL1, TL2, TL3, TL4, and TL5 may include the first trace line TL1, the second trace line TL2, the third trace line TL3, the fourth trace line TL4, and the fifth trace line TL5.

The plurality of trace lines TL1, TL2, TL3, TL4, and TL5 may transfer a common voltage or the touch sensing signal Tx (refer to FIG. 3) to the plurality of touch electrodes TSP. In an embodiment, for example, in the first mode, the common voltage may be provided to the plurality of touch electrodes TSP, and in the second mode, the touch sensing signal Tx may be provided to the plurality of touch electrodes TSP. In an embodiment, each of the plurality of touch electrodes TSP may be electrically connected with the first switch SW1 (refer to FIG. 3) and the second switch SW2 (refer to FIG. 3). In the first mode, the first switch SW1 may be turned on, and the second switch SW2 may be turned off. In this case, each of the plurality of touch electrodes TSP may receive the common voltage through the first switch SW1. In the second mode, the first switch SW1 may be turned off, and the second switch SW2 may be turned on. In this case, each of the plurality of touch electrodes TSP may receive the touch sensing signal Tx through the second switch SW2.

In an embodiment, the first trace line TL1 may be electrically connected with the first touch electrode TSPI and may transfer the common voltage or the touch sensing signal Tx to the first touch electrode TSP1, and the second trace line TL2 may be electrically connected with the second touch electrode TSP2 and may transfer the common voltage or the touch sensing signal Tx to the second touch electrode TSP2. In such an embodiment, the third trace line TL3 may be electrically connected with the third touch electrode TSP3 and may transfer the common voltage or the touch sensing signal Tx to the third touch electrode TSP3, the fourth trace line TL4 may be electrically connected with the fourth touch electrode TSP4 and may transfer the common voltage or the touch sensing signal Tx to the fourth touch electrode TSP4, and the fifth trace line TL5 may be electrically connected with the fifth touch electrode TSP5 and may transfer the common voltage or the touch sensing signal Tx to the fifth touch electrode TSP5.

Some of the plurality of trace lines TL1, TL2, TL3, TL4, and TL5 may extend along the peripheries of the regions in which the plurality of touch electrodes TSP are disposed, and the others may extend between the plurality of touch electrodes TSP. In an embodiment, for example, the first, third, fourth, and fifth trace lines TL1, TL3, TL4, and TL5 may extend along the peripheries of the regions in which the plurality of touch electrodes TSP are disposed, and the second trace line TL2 may extend between the fourth touch electrode TSP4 and the fifth touch electrode TSP5. However, this is illustrative, and an arrangement of the plurality of trace lines TL1, TL2, TL3, TL4, and TL5 is not limited thereto.

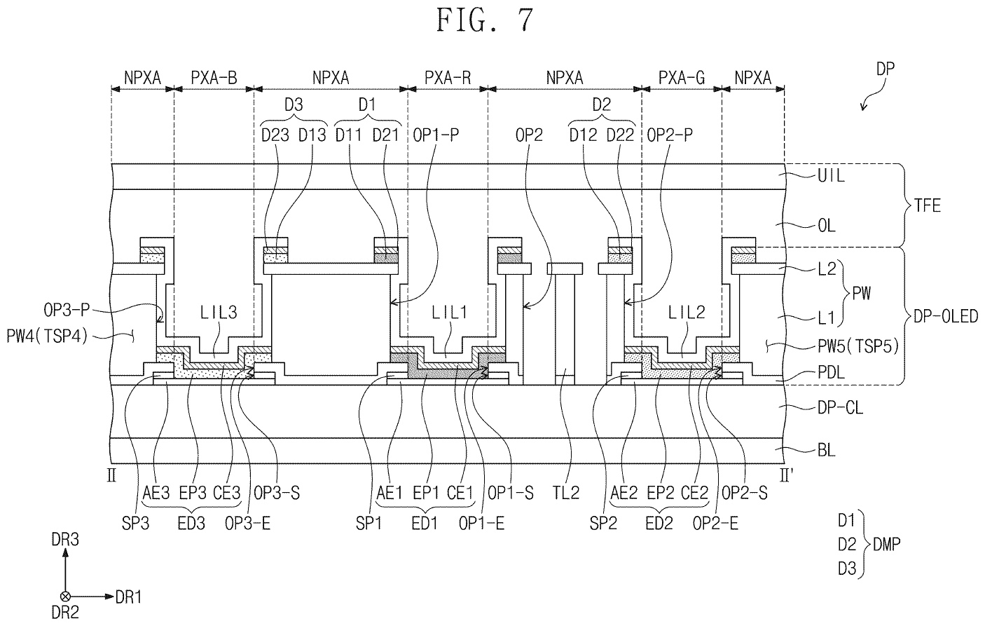

FIG. 6 is a sectional view of the display panel DP taken along line I-I′ of FIG. 5, and FIG. 7 is a sectional view of the display panel DP taken along line II-II′ of FIG. 5. FIGS. 6 and 7 are enlarged views of one first emissive region PXA-R, one second emissive region PXA-G, and one third emissive region PXA-B, and the description or features of the emissive region PXA of FIG. 4 may be identically applied to each of the first to third emissive regions PXA-R, PXA-G, and PXA-B. In describing FIGS. 6 and 7, the description will be made with further reference to FIGS. 4 and 5, and any repetitive detailed descriptions of the same elements labeled with the same reference numerals as those described above will be omitted.

Referring to FIGS. 6 and 7, the display panel DP according to an embodiment may include the base layer BL, the circuit layer DP-CL, the display element layer DP-OLED, and the thin film encapsulation layer TFE. The display element layer DP-OLED may include the light emitting elements ED1, ED2, and ED3, sacrificial patterns SP1, SP2, and SP3, the pixel defining layer PDL, the barrier wall PW, and dummy patterns DMP.

The light emitting elements ED1, ED2, and ED3 may include the first light emitting element ED1, the second light emitting element ED2, and the third light emitting element ED3. The first light emitting element ED1 may include a first anode AE1, a first emission pattern EP1, and a first cathode CE1. The second light emitting element ED2 may include a second anode AE2, a second emission pattern EP2, and a second cathode CE2. The third light emitting element ED3 may include a third anode AE3, a third emission pattern EP3, and a third cathode CE3. The first to third anodes AE1, AE2, and AE3 may be provided in or defined by a plurality of patterns. In an embodiment, the first emission pattern EP1 may provide red light, the second emission pattern EP2 may provide green light, and the third emission pattern EP3 may provide blue light.

First to third light emitting openings OP1-E, OP2-E, and OP3-E may be defined in the pixel defining layer PDL. The first light emitting opening OP1-E may expose at least a portion of the first anode AE1. The first emissive region PXA-R may be defined as a region of an upper surface of the first anode AE1 exposed by the first light emitting opening OP1-E. The second light emitting opening OP2-E may expose at least a portion of the second anode AE2. The second emissive region PXA-G may be defined as a region of an upper surface of the second anode AE2 exposed by the second light emitting opening OP2-E. The third light emitting opening OP3-E may expose at least a portion of the third anode AE3. The third emissive region PXA-B may be defined as a region of an upper surface of the third anode AE3 exposed by the third light emitting opening OP3-E.

The sacrificial patterns SP1, SP2, and SP3 may include the first sacrificial pattern SP1, the second sacrificial pattern SP2, and the third sacrificial pattern SP3. The first to third sacrificial patterns SP1, SP2, and SP3 may be disposed on the upper surfaces of the first to third anodes AE1, AE2, and AE3, respectively. First to third sacrificial openings OP1-S, OP2-S, and OP3-S corresponding to the first to third light emitting openings OP1-E, OP2-E, and OP3-E may be defined in the first to third sacrificial patterns SP1, SP2, and SP3.

First to third barrier openings OP1-P, OP2-P, and OP3-P corresponding to the first to third light emitting openings OP1-E, OP2-E, and OP3-E may be defined in the barrier wall PW. The first emission pattern EP1 and the first cathode CE1 may be disposed in the first barrier opening OP1-P, the second emission pattern EP2 and the second cathode CE2 may be disposed in the second barrier opening OP2-P, and the third emission pattern EP3 and the third cathode CE3 may be disposed in the third barrier opening OP3-P. The first to third cathodes CE1, CE2, and CE3 may contact first inner surfaces of the first barrier wall layer L1.

In an embodiment, the first to third cathodes CE1, CE2, and CE3 may be physically separated by the second barrier wall layer L2 that forms tip portions and may be formed in the light emitting openings OP1-E, OP2-E, and OP3-E. The first to third cathodes CE1, CE2, and CE3 may contact the first barrier wall layer L1 and may be electrically connected with the first barrier wall layer L1 to receive the common voltage. The first barrier wall layer L1 may have a higher electrical conductivity than the second barrier wall layer L2 and thus may decrease contact resistance with the first to third cathodes CE1, CE2, and CE3. Accordingly, a common cathode voltage may be uniformly provided for the emissive regions PXA-R, PXA-G, and PXA-B.

According to an embodiment of the disclosure, a plurality of first emission patterns EP1 may be patterned and deposited (or separately provided) in pixel units by tip portions defined in the barrier wall PW. In such an embodiment, the first emission patterns EP1 may be commonly formed by using an open mask, but may be easily divided in pixel units by the barrier wall PW.

In a case in which the first emission patterns EP1 are patterned by using a fine metal mask (FMM), a spacer for support that protrudes from the barrier wall has to be provided to support the fine metal mask. In this case, since the fine metal mask is spaced, by the height of the barrier wall and the spacer, apart from a base surface on which patterning is performed, there may be a limitation in the implementation of high resolution. In addition, since the fine metal mask is brought into contact with the spacer, foreign matter may remain on the spacer after the patterning process of the first emission patterns EP1, or the spacer may be damaged by a dent defect of the fine metal mask. Therefore, a defective display panel may be formed.

According to an embodiment, since the barrier wall PW is included, the physical separation between the light emitting elements ED1, ED2, and ED3 may be easily achieved. Accordingly, current leakage or a driving error between the adjacent emissive regions PXA-R, PXA-G, and PXA-B may be effectively prevented, and the light emitting elements ED1, ED2, and ED3 may be independently driven.

In such an embodiment, by patterning the plurality of first emission patterns EP1 without using a mask in contact with an internal component in the display region DA (refer to FIG. 1B), a defect rate may be reduced, and thus the display panel DP having improved process reliability may be provided. Since patterning is possible even though the separate spacer for support that protrudes from the barrier wall PW is not provided, the areas of the emissive regions PXA-R, PXA-G, and PXA-B may be scaled down, and thus the display panel DP capable of easily implementing high resolution may be provided.

Furthermore, in the manufacture of the large-area display panel DP, the manufacture of a large-area mask may be omitted. Accordingly, process costs may be reduced, and the display panel DP may not be affected by defects that are likely to occur in the large-area mask. Thus, the display panel DP having improved process reliability may be provided.

In an embodiment of the disclosure, the display panel DP may further include first to third capping patterns. The first to third capping patterns may be disposed on the first to third cathodes CE1, CE2, and CE3 and may be disposed in the first to third barrier openings OP1-P, OP2-P, and OP3-P.

The dummy patterns DMP may include a plurality of first dummy patterns D1, a plurality of second dummy patterns D2, and a plurality of third dummy patterns D3. The plurality of first dummy patterns D1 may include a first first dummy pattern (hereinafter, will be referred to as “dummy pattern 1-1”) D11 and a second first dummy pattern (hereinafter, will be referred to as “dummy pattern 2-1”) D21, the plurality of second dummy patterns D2 may include a first second dummy pattern (hereinafter, will be referred to as “dummy pattern 1-2”) D12 and a second second dummy pattern (hereinafter, will be referred to as “dummy pattern 2-2”) D22, and the plurality of third dummy patterns D3 may include a first third dummy pattern (hereinafter, will be referred to as “dummy pattern 1-3”) D13 and a second third dummy pattern (hereinafter, will be referred to as “dummy pattern 2-3”) D23.

The dummy patterns DMP may include the dummy pattern 1-1 D11, the dummy pattern 1-2 D12, and the dummy pattern 1-3 D13 that surround the first to third emissive regions PXA-R, PXA-G, and PXA-B, respectively, on the plane. The dummy pattern 1-1 D11, the dummy pattern 1-2 D12, and the dummy pattern 1-3 D13 may include a same material as the first to third emission patterns EP1, EP2, and EP3 and may be formed through a same process as the first to third emission patterns EP1, EP2, and EP3.

The dummy patterns DMP may include the dummy pattern 2-1 D21, the dummy pattern 2-2 D22, and the dummy pattern 2-3 D23 that surround the first to third emissive regions PXA-R, PXA-G, and PXA-B, respectively, on the plane. The dummy pattern 2-1 D21, the dummy pattern 2-2 D22, and the dummy pattern 2-3 D23 may include a same material as the first to third cathodes CE1, CE2, and CE3 and may be formed through a same process as the first to third cathodes CE1, CE2, and CE3.

The thin film encapsulation layer TFE may include lower inorganic encapsulation patterns LIL1, LIL2, and LIL3, the organic encapsulation film OL, and the upper inorganic encapsulation film UIL. In an embodiment, the lower inorganic encapsulation patterns LIL1, LIL2, and LIL3 may include the first lower inorganic encapsulation pattern LIL1, the second lower inorganic encapsulation pattern LIL2, and the third lower inorganic encapsulation pattern LIL3. The first to third lower inorganic encapsulation patterns LIL1, LIL2, and LIL3 may correspond to the first to third light emitting openings OP1-E, OP2-E, and OP3-E, respectively.

The first lower inorganic encapsulation pattern LIL1 may cover the first light emitting element ED1, the dummy pattern 1-1 D11, and the dummy pattern 2-1 D21 and may be partially disposed in the first barrier opening OP1-P. The second lower inorganic encapsulation pattern LIL2 may cover the second light emitting element ED2, the dummy pattern 1-2 D12, and the dummy pattern 2-2 D22 and may be partially disposed in the second barrier opening OP2-P. The third lower inorganic encapsulation pattern LIL3 may cover the third light emitting element ED3, the dummy pattern 1-3 D13, and the dummy pattern 2-3 D23 and may be partially disposed in the third barrier opening OP3-P. The first to third lower inorganic encapsulation patterns LIL1, LIL2, and LIL3 may be provided in pattern forms spaced apart from each other.

The organic encapsulation film OL may cover the lower inorganic encapsulation patterns LIL1, LIL2, and LIL3 and the barrier wall PW and may provide a flat upper surface. The upper inorganic encapsulation film UIL may be disposed on the organic encapsulation film OL.

In FIG. 6, a portion of the first touch electrode TSP1 and a portion of the second touch electrode TSP2 are illustrated. Referring to FIGS. 5 and 6, a first opening OP1 may be defined in the display panel DP. The first opening OP1 may be formed between the first touch electrode TSP1 and the second touch electrode TSP2. The first touch electrode TSPI and the second touch electrode TSP2 may be spaced apart from each other by the first opening OP1 and may be disconnected from each other. The first opening OP1 may be formed together when one of the first to third barrier openings OP1-P, OP2-P, and OP3-P is formed. Thereafter, the organic encapsulation film OL may cover the first opening OP1. Detailed description thereabout will be given below.

In FIG. 7, a portion of the fourth touch electrode TSP4 and a portion of the fifth touch electrode TSP5 are illustrated. Referring to FIGS. 5 and 7, a second opening OP2 may be defined in the display panel DP. The second opening OP2 may be formed between the fourth touch electrode TSP4 and the fifth touch electrode TSP5. The fourth touch electrode TSP4 and the fifth touch electrode TSP5 may be spaced apart from each other by the second opening OP2 and may be disconnected from each other.

The trace line TL1, TL2, TL3, TL4, or TL5 (refer to FIG. 5) extending between the plurality of touch electrodes TSP may be disposed in the second opening OP2. F In an embodiment, for or example, the second trace line TL2 may be disposed or formed between the fourth touch electrode TSP4 and the fifth touch electrode TSP5 and may transfer the touch sensing signal Tx (refer to FIG. 3) to the second touch electrode TSP2. The second opening OP2 and the second trace line TL2 may be formed together when one of the first to third barrier openings OP1-P, OP2-P, and OP3-P is formed. Thereafter, the organic encapsulation film OL may cover the second opening OP2 and the second trace line TL2.

The first opening OP1 formed between the first touch electrode TSP1 and the second touch electrode TSP2 is illustrated in FIG. 6, and the second opening OP2 and the second trace line TL2 formed between the fourth touch electrode TSP4 and the fifth touch electrode TSP5 are illustrated in FIG. 7. However, this is illustrative. In an embodiment, the first to fifth touch electrodes TSP1, TSP2, TSP3, TSP4, and TSP5 (refer to FIG. 5) may be spaced apart from each other and may be disconnected from each other, and an opening may be defined or formed between two touch electrodes TSP (refer to FIG. 5) that are spaced apart from each other.

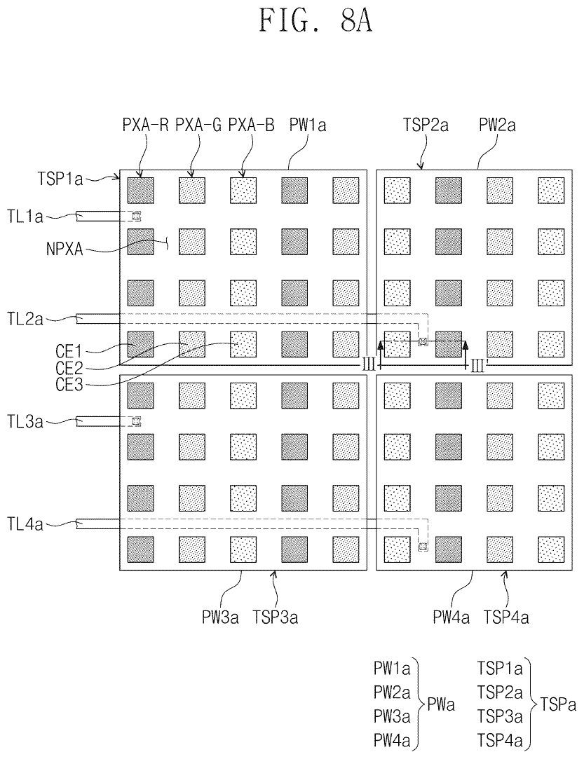

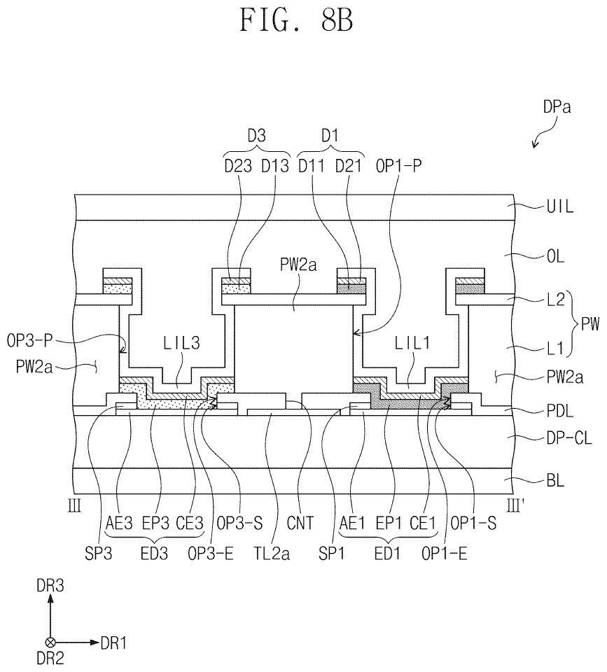

FIG. 8A is a plan view illustrating a part of a plurality of touch electrodes TSPa of a display panel DPa (refer to FIG. 8B) according to an embodiment of the disclosure. In describing FIG. 8A, the description will be made with further reference to FIG. 5, and any repetitive detailed descriptions of the same elements labeled with the same reference numerals as those described above will be omitted.

Referring to FIG. 8A, in an embodiment, the display panel DPa may include the plurality of touch electrodes TSPa disposed between a circuit layer DP-CL (refer to FIG. 6) and a thin film encapsulation layer TFE (refer to FIG. 6). The plurality of touch electrodes TSPa may include first to fourth touch electrodes TSP1a, TSP2a, TSP3a, and TSP4a. The first to fourth touch electrodes TSP1a, TSP2a, TSP3a, and TSP4a may be spaced apart from each other.

A barrier wall PWa may include a plurality of barrier wall patterns PW1a, PW2a, PW3a, and PW4a. The plurality of barrier wall patterns PW1a, PW2a, PW3a, and PW4a may be spaced apart from each other. First to third barrier openings OP1-P, OP2-P, and OP3-P (refer to FIG. 5) corresponding to first to third emissive regions PXA-R, PXA-G, and PXA-G may be defined or formed by each of the plurality of barrier wall patterns PW1a, PW2a, PW3a, and PW4a.

Each of the plurality of touch electrodes TSPa may include a corresponding barrier wall pattern among the plurality of barrier wall patterns PW1a, PW2a, PW3a, and PW4a and may include some corresponding cathodes among a plurality of cathodes CE1, CE2, and CE3. In an embodiment, for example, the first touch electrode TSP1a may include the first barrier wall pattern PW1aand some of the first to third cathodes CE1, CE2, and CE3 corresponding to the first barrier wall pattern PW1a, and the second touch electrode TSP2a may include the second barrier wall pattern PW2a and some of the first to third cathodes CE1, CE2, and CE3 corresponding to the second barrier wall pattern PW2a. In such an embodiment, the third touch electrode TSP3a may include the third barrier wall pattern PW3a and some of the first to third cathodes CE1, CE2, and CE3 corresponding to the third barrier wall pattern PW3a, and the fourth touch electrode TSP4a may include the fourth barrier wall pattern PW4a and some of the first to third cathodes CE1, CE2, and CE3 corresponding to the fourth barrier wall pattern PW4a.

The display panel DPa may further include a plurality of trace lines TL1a, TL2a, TL3a, and TL4a electrically connected with the plurality of touch electrodes TSPa. The plurality of trace lines TL1a, TL2a, TL3a, and TL4a may include the first trace line TL1a, the second trace line TL2a, the third trace line TL3a, and the fourth trace line TL4a. The first to fourth trace lines TL1a, TL2a, TL3a, and TL4a may be electrically connected with the first to fourth touch electrodes TSP1a, TSP2a, TSP3a, and TSP4a, respectively. The first to fourth trace lines TL1a, TL2a, TL3a, and TL4a may transfer a common voltage to the plurality of touch electrodes TSPa in a first mode and may transfer a touch sensing signal Tx (refer to FIG. 3) to the plurality of touch electrodes TSPa in a second mode.

Some of the plurality of trace lines TL1a, TL2a, TL3a, and TL4a may overlap the plurality of touch electrodes TSPa on the plane. The plurality of trace lines TL1a, TL2a, TL3a, and TL4a may extend to be connected with the plurality of touch electrodes TSPa on a section and extending to overlap the plurality of touch electrodes TSPa on the plane.

FIG. 8B is a sectional view of the display panel DPa taken along line III-III′ of FIG. 8A. In describing FIG. 8B, the description will be made with further reference to FIG. 6, and any repetitive detailed descriptions of the same elements labeled with the same reference numerals as those described above will be omitted.

Referring to FIGS. 8A and 8B, in an embodiment, each of the plurality of trace lines TL1a, TL2a, TL3a, and TL4a may be disposed in (or directly on) a same layer as an anode AE (refer to FIG. 4) and may include a same material as the anode AE. Each of the plurality of trace lines TL1a, TL2a, TL3a, and TL4a may be connected with a corresponding barrier wall pattern PW1a, PW2a, PW3a, or PW4a through a contact hole CNT defined in a pixel defining layer PDL. Accordingly, each of the plurality of trace lines TLa, TL2a, TL3a, and TL4a may be electrically connected to the plurality of touch electrodes TSPa and may transfer the common voltage or the touch sensing signal Tx (refer to FIG. 3). In an embodiment, for example, the second trace line TL2a may be connected with the second barrier wall pattern PW2a through the contact hole CNT defined in the pixel defining layer PDL. Accordingly, the second trace line TL2a may be electrically connected to the second touch electrodes TSP2a and may transfer the common voltage or the touch sensing signal Tx (refer to FIG. 3).

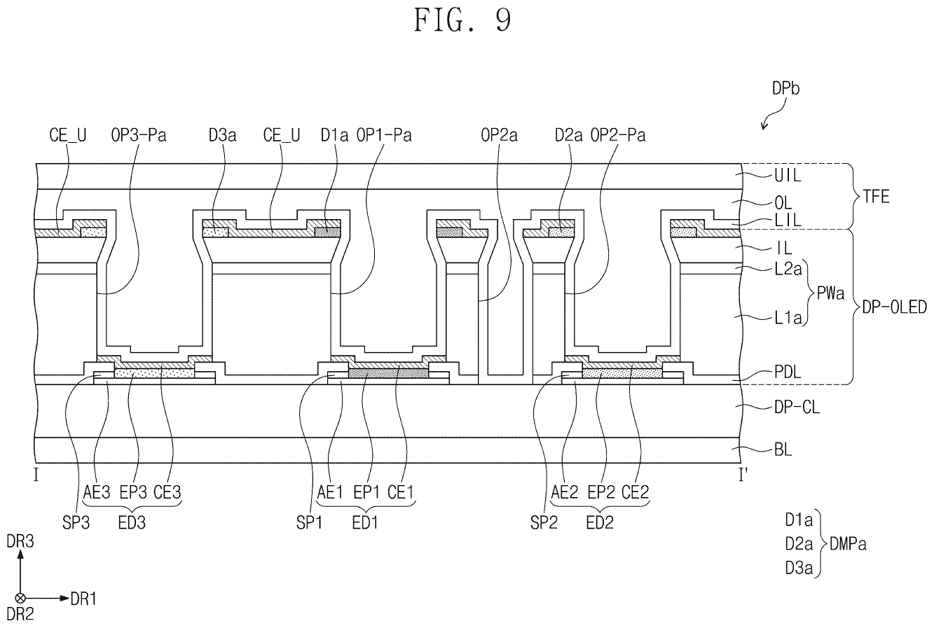

FIG. 9 is a sectional view of the display panel DP taken along line I-I′ of FIG. 5. In describing FIG. 9, the description will be made with further reference to FIG. 6, and any repetitive detailed descriptions of the same elements labeled with the same reference numerals as those described above will be omitted.

Referring to FIG. 9, in an embodiment, the display panel DP may include the base layer BL, the circuit layer DP-CL, the display element layer DP-OLED, and the thin film encapsulation layer TFE. The display element layer DP-OLED may include the light emitting elements ED1, ED2, and ED3, the sacrificial patterns SP1, SP2, and SP3, the pixel defining layer PDL, a barrier wall PWa, an insulating layer IL, upper cathodes CE_U, and dummy patterns DMPa.

The barrier wall PWa may include a first barrier wall layer L1a and a second barrier wall layer L2a. The first barrier wall layer L1a may be disposed on the pixel defining layer PDL, and the second barrier wall layer L2a may be disposed on the first barrier wall layer L1a. The first barrier wall layer L1a may have a first conductivity and a first thickness, and the second barrier wall layer L2a may have a second conductivity and a second thickness. The first conductivity may be higher than the second conductivity, and the first thickness may be greater than the second thickness. First inner surfaces of the first barrier wall layer L1a and second inner surfaces of the second barrier wall layer L2a may be aligned with each other.

First to third barrier openings OP1-Pa, OP2-Pa, and OP3-Pa corresponding to the first to third light emitting openings OP1-E, OP2-E, and OP3-E and a second opening OP2a disposed between the first light emitting opening OP1-E and the second light emitting opening OP2-E may be defined in the barrier wall PWa. The first emission pattern EP1 and the first cathode CE1 may be disposed in the first barrier opening OP1-Pa, the second emission pattern EP2 and the second cathode CE2 may be disposed in the second barrier opening OP2-Pa, and the third emission pattern EP3 and the third cathode CE3 may be disposed in the third barrier opening OP3-Pa.

The first to third cathodes CE1, CE2, and CE3 may contact the first inner surfaces of the first barrier wall layer L1a.

In an embodiment, the insulating layer IL may be disposed on the barrier wall PWa. The insulating layer IL may have an inverted tapered shape. In such an embodiment, the insulating layer IL and the barrier wall PWa may have an undercut shape on the section. The inner surfaces of the barrier wall PWa may be recessed with respect to the plurality of light emitting elements ED1, ED2, and ED3, compared to inner surfaces of the insulating layer IL. The insulating layer IL may include an insulating material. The insulating layer IL may be disposed between the barrier wall PWa and the upper cathodes CE_U and may effectively prevent electrical connection between the barrier wall PWa and the upper cathodes CE_U.

The first emission pattern EP1 may be physically separated by a tip portion defined by the insulating layer IL and may be formed in the first light emitting opening OP1-E. A first dummy pattern D1a may include a same material as the first emission pattern EP1. The first dummy pattern D1a may be simultaneously formed with the first emission pattern EP1 through a same process and may be separated from the first emission pattern EP1 by the undercut shapes of the insulating layer IL and the barrier wall PWa.

The second emission pattern EP2 may be physically separated by a tip portion defined by the insulating layer IL and may be formed in the second light emitting opening OP2-E. A second dummy pattern D2a may include a same material as the second emission pattern EP2. The second dummy pattern D2a may be simultaneously formed with the second emission pattern EP2 through a same process and may be separated from the second emission pattern EP2 by the undercut shapes of the insulating layer IL and the barrier wall PWa.

The third emission pattern EP3 may be physically separated by a tip portion defined by the insulating layer IL and may be formed in the third light emitting opening OP3-E. A third dummy pattern D3a may include a same material as the third emission pattern EP3. The third dummy pattern D3a may be simultaneously formed with the third emission pattern EP3 through a same process and may be separated from the third emission pattern EP3 by the undercut shapes of the insulating layer Il and the barrier wall PWa.

In such an embodiment, the first to third cathodes CE1, CE2, and CE3 may be physically separated by the insulating layer IL that forms the tip portions and may be formed in the light emitting openings OP1-E, OP2-E, and OP3-E. The first to third cathodes CE1, CE2, and CE3 may contact the first barrier wall layer L1a and may be electrically connected with the first barrier wall layer L1a to receive the common voltage. The first barrier wall layer L1a may have a higher electrical conductivity than the second barrier wall layer L2a and thus may decrease contact resistance with the first to third cathodes CE1, CE2, and CE3. Accordingly, the common cathode voltage may be uniformly provided for the emissive regions PXA-R. PXA-G, and PXA-B.

The upper cathodes CE_U may include a same material as the first to third cathodes CE1, CE2, and CE3. The upper cathodes CE_U may be formed through a same process as the first to third cathodes CE1, CE2, and CE3. The upper cathodes CE_U may be simultaneously formed with the corresponding cathodes through a same process and may be separated from the first to third cathodes CE1, CE2, and CE3 by the undercut shapes of the insulating layer IL and the barrier wall PWa.

The insulating layer IL may be disposed between the barrier wall PWa and the upper cathodes CE_U and may prevent electrical connection between the barrier wall PWa and the upper cathodes CE_U. Thus, the upper cathodes CE_U may be used as touch electrodes of the display panel DPb. The plurality of upper cathodes CE_U (or the plurality of touch electrodes) disposed on the barrier wall PWa may function as one of the plurality of touch electrodes TSP of FIG. 5. In such an embodiment, the insulating layer IL may be disposed between the barrier wall PWa and the plurality of touch electrodes CE_U and may insulate the barrier wall PWa from the plurality of touch electrodes CE_U.

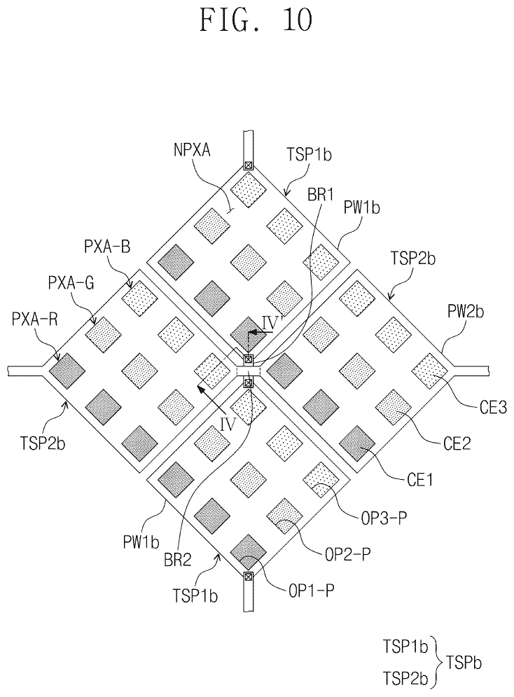

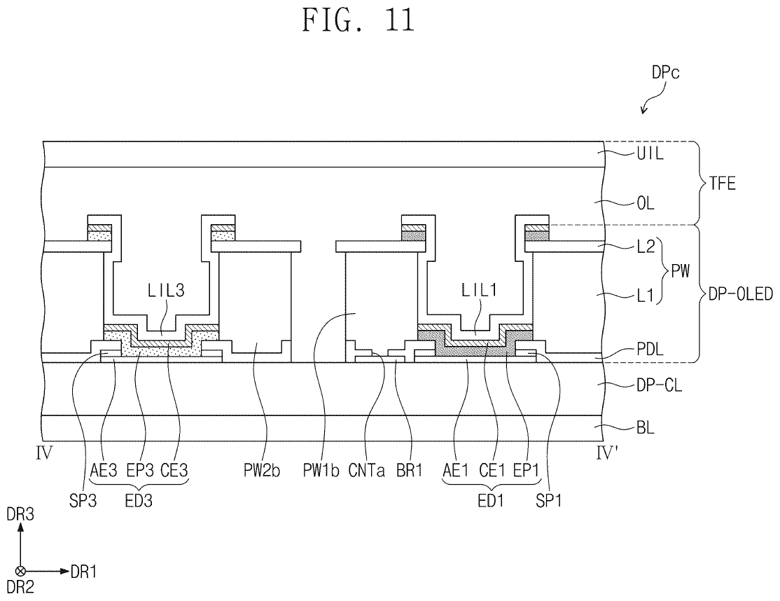

FIG. 10 is a plan view illustrating a plurality of touch electrodes TSPb of a display panel according to an embodiment of the disclosure. FIG. 11 is a sectional view taken along line IV-IV′ of FIG. 10. In describing FIG. 10, the description will be made with further reference to FIG. 5, and any repetitive detailed descriptions of the same elements labeled with the same reference numerals as those described above will be omitted.

Referring to FIGS. 10 and 11, in an embodiment, the display panel DPc may include the plurality of touch electrodes TSPb. The plurality of touch electrodes TSPb may be disposed between a circuit layer DP-CL and a thin film encapsulation layer TFE. The plurality of touch electrodes may include a first touch electrode TSP1 and a second touch electrode TSP2b.

The first touch electrode TSP1b may include a first sensing pattern PW1b (or, a first barrier wall pattern) and a bridge pattern BR1, and the second touch electrode TSP2b may include a second sensing portion PW2b (or a second barrier wall pattern) and a bridge portion BR2. The bridge pattern BRI may electrically connect the first sensing pattern PW1b, and the bridge portion BR2 may electrically connect the second sensing portion PW2b. The bridge portion BR2 may have an integrated shape that is not separated from the second sensing portion PW2b, that is, be integrally formed with the second sensing portion PW2b as a single unitary and indivisible part.

The first sensing pattern PW1b, the second sensing portion PW2b, and the bridge portion BR2 may be disposed in (or directly on) a same layer, and the bridge pattern BRI may be disposed in (or directly on) a layer different from the layer in (or directly on) which the first sensing pattern PW1b, the second sensing portion PW2b, and the bridge portion BR2 are disposed. In an embodiment, for example, the bridge pattern BRI may be disposed in (or directly on) a same layer as an anode AE1 or AE3 and may include a same material as the anode AE1 or AE3. The bridge pattern BRI may be connected with the first sensing pattern PW1b through a contact hole CNTa defined in a pixel defining layer. Accordingly, the bridge pattern BRI may be electrically connected with the first sensing pattern TSP1b and may transfer a common voltage or a touch sensing signal Tx (refer to FIG. 3).

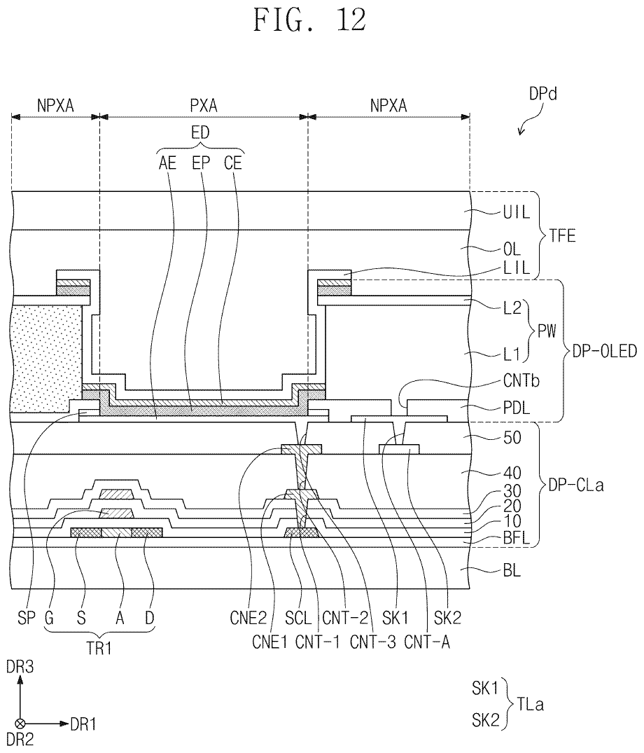

FIG. 12 is a sectional view of a portion of a display panel DPd according to an embodiment of the disclosure. In describing FIG. 12, the description will be made with further reference to FIG. 4, and any repetitive detailed descriptions of the same elements labeled with the same reference numerals as those described above will be omitted.

Referring to FIG. 12, in an embodiment, a trace line TLa may include a first sub-layer SKI and a second sub-layer SK2. The first sub-layer SKI may be disposed in (or directly on) a same layer as an anode AE and may include a same material as the anode AE. The second sub-layer SK2 may be disposed under the first sub-layer SKI and may be electrically connected with the first sub-layer SK1. The second sub-layer SK2 may be included in a circuit layer DP-CLa. The trace line TLa of FIG. 11 may correspond to the plurality of trace lines TL1, TL2, TL3, TL4, and TL5 of FIG. 5 or the bridge pattern BRI of FIG. 10.

A barrier wall PW may be connected with the first sub-layer SKI through a contact hole CNTb defined in a pixel defining layer PDL, and the first sub-layer SKI may be connected with the second sub-layer SK2 through an auxiliary contact hole CNT-A defined in a fifth insulating layer 50. That is, the trace line TLa may be connected with the barrier wall PW through the contact hole CNTb and the auxiliary contact hole CNT-A. Accordingly, the trace line TLa may be electrically connected to a plurality of touch electrodes TSP, TSPa, or TSPb (refer to FIG. 5, 8A, or 10) and may transfer a common voltage or a touch sensing signal Tx (refer to FIG. 3).

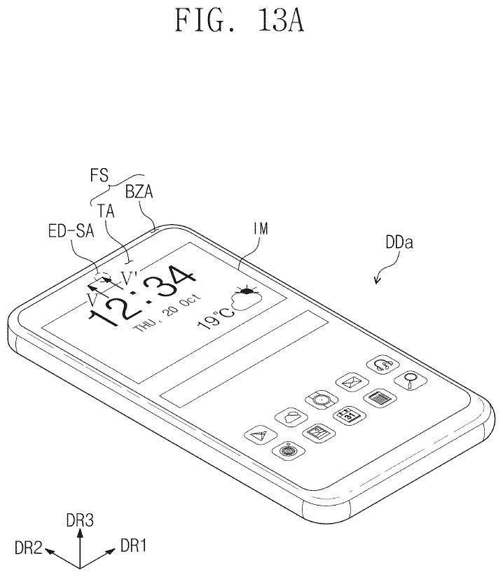

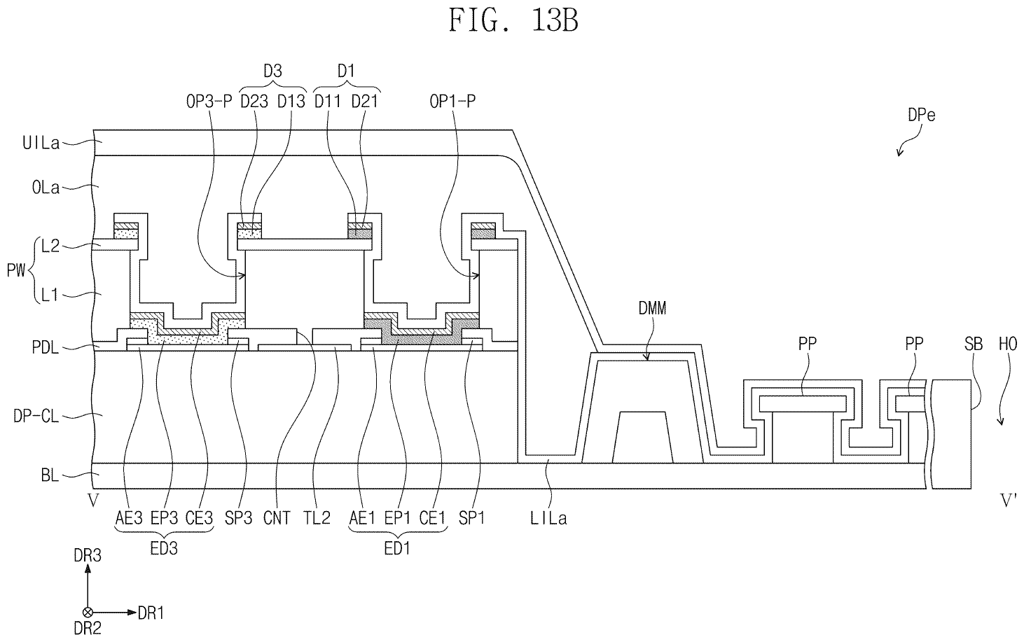

FIG. 13A is a perspective view of a display device DDa according to an embodiment of the disclosure. In describing FIG. 13A, the description will be made with reference to FIG. 1A, and any repetitive detailed descriptions of the same elements labeled with the same reference numerals as those described above will be omitted.

A sensor region ED-SA may be defined in a display region DA (refer to FIG. 1B) of the display device DDa. Although an embodiment where a single sensor region ED-SA is defined in a display region DA is illustrated in FIG. 13A as an example, the number of sensor regions ED-SA is not limited thereto. The sensor region ED-SA may be surrounded by the display region DA. Accordingly, the display device DDa does not display an image through the senor region ED-SA.

In an embodiment, an electronic module may be disposed in a region overlapping the sensor region ED-SA. The electronic module may receive an external input transferred through the sensor region ED-SA, or may provide an output through the sensor region ED-SA. In an embodiment, for example, the electronic module may be a camera module, a sensor (e.g., a proximity sensor) that measures a distance, a sensor that recognizes a part of a user's body (e.g., a fingerprint, an iris, or a face), or a small lamp that outputs light, but is not particularly limited thereto. Hereinafter, for convenience of description, embodiments where the electronic module overlapping the sensor region ED-SA is a camera module will be described in detail.

FIG. 13B is a sectional view of a display panel DPe taken along line V-V′ of FIG. 13A. In describing FIG. 13B, the description will be made with further reference to FIG. 8B, and any repetitive detailed descriptions of the same elements labeled with the same reference numerals as those described above will be omitted.

Referring to FIGS. 13A and 13B, in an embodiment, the display panel DPe may include a sidewall SB that defines a hole HO. In an embodiment, for example, the hole HO may be defined by removing a portion of the display panel DPe. The hole HO may be defined in a base layer BL. The display region DA (refer to FIG. 1B) of the display panel DPe may surround the hole HO. The hole HO may overlap, or correspond to, the sensor region ED-SA of the display device DDa. Although an embodiment where the hole HO is in a circular shape is illustrated, the hole HO may have various shapes, such as a polygonal shape, an oval shape, a shape having at least one curved side, or an irregular shape, and is not limited to any one embodiment.

The display panel DPe may include a dam DMM disposed adjacent to the hole HO and a plurality of protrusions PP. The dam DMM may be provided to control a flow of monomer in a process of forming an organic encapsulation film OLa. Although one dam DMM is illustrated as an example in FIG. 13B, the disclosure is not particularly limited thereto. The display panel DPe may include two or more dams DMM. The dam DMM may include a first layer simultaneously formed with a fifth insulating layer 50 (refer to FIG. 4) of a circuit layer DP-CL and a second layer simultaneously formed with a pixel defining layer PDL, but is not particularly limited thereto.

The plurality of protrusions PP may be disposed on the base layer BL. The plurality of protrusions PP may be disposed between a pixel PX (refer to FIG. 2) and the hole HO. In an embodiment, for example, the plurality of protrusions PP may be disposed between the dam DMM and the sidewall SB. The plurality of protrusions PP may surround at least a portion of the hole HO. The plurality of protrusions PP may be provided to isolate light emitting elements ED1 and ED3 from the hole HO. Furthermore, the plurality of protrusions PP may serve to prevent propagation of a crack progressing from the sidewall SB. Each of the plurality of protrusions PP may have a multi-tip structure.

The plurality of protrusions PP may include a same material as a barrier wall PW and may be formed through a same process as the barrier wall PW. Since the plurality of protrusions PP are formed through a same process as the barrier wall PW, the efficiency of a display panel manufacturing process may be improved.

Although two protrusions PP arranged at equal intervals are illustrated as an example in FIG. 13B, the disclosure is not particularly limited thereto. In an embodiment, for example, some of the protrusions PP may be omitted, and more protrusions PP may be disposed. Alternatively, the intervals between the protrusions PP may differ from one another.

A lower inorganic encapsulation pattern LILa may cover the light emitting elements ED1 and ED3 and dummy patterns D1 and D3, and a portion of the lower inorganic encapsulation pattern LILa may be disposed in barrier openings OP1-P and OP3-P. Furthermore, the lower inorganic encapsulation pattern LILa may extend along the base layer BL and may cover the dam DMM and the plurality of protrusions PP.

The organic encapsulation film OLa may cover the lower inorganic encapsulation pattern LILa and may provide a flat upper surface. In an embodiment, the organic encapsulation film OLa may cover a portion of the lower inorganic encapsulation pattern LILa extending from the light emitting elements ED1 and ED3 toward the hole HO. The organic encapsulation film OLa may cover the lower inorganic encapsulation pattern LILa that covers a side surface of the dam DMM.

An upper inorganic encapsulation film UILa may be disposed on the lower inorganic encapsulation pattern LILa and the organic encapsulation film OLa and may cover the lower inorganic encapsulation pattern LILa and the organic encapsulation film OLa.

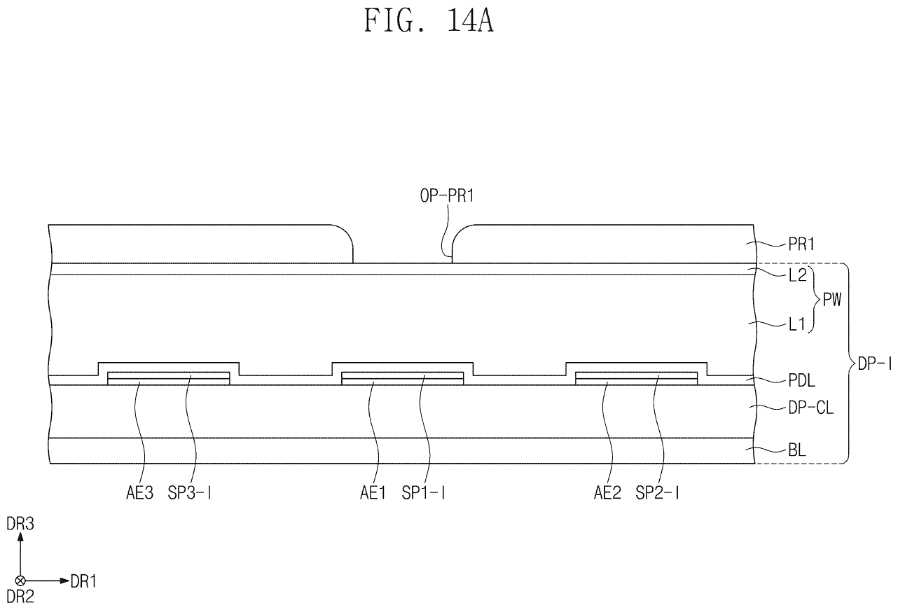

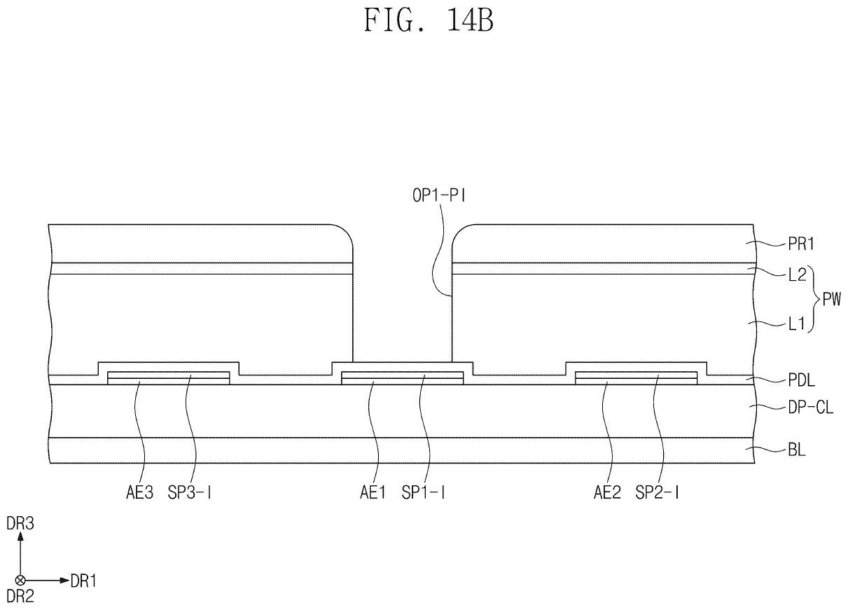

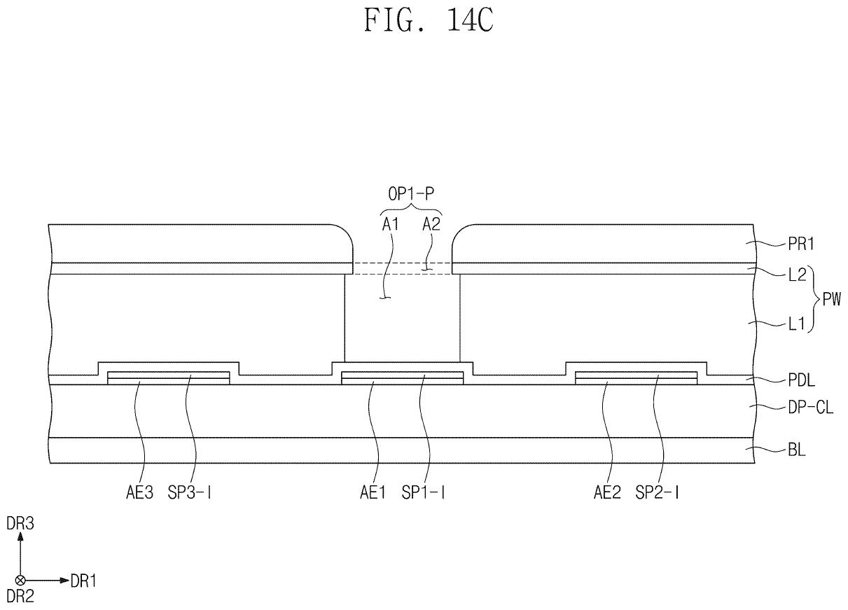

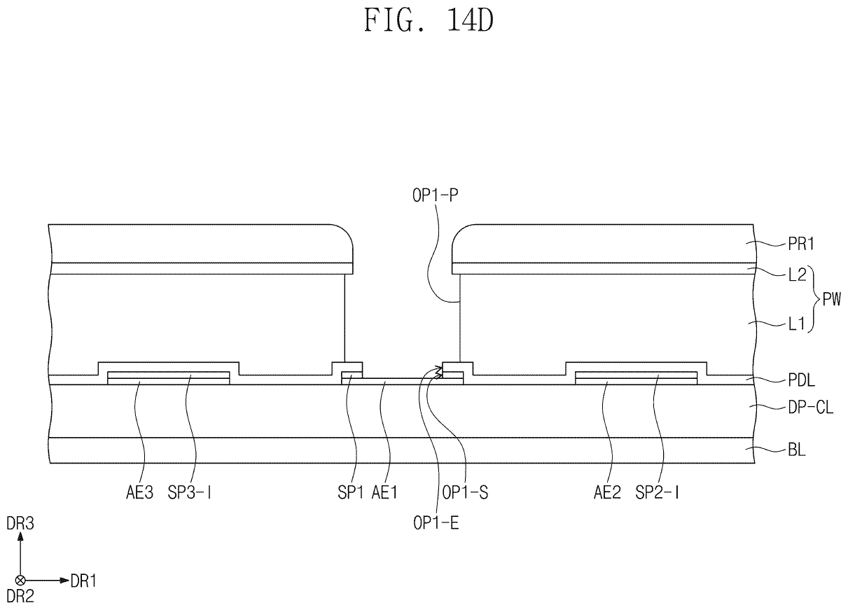

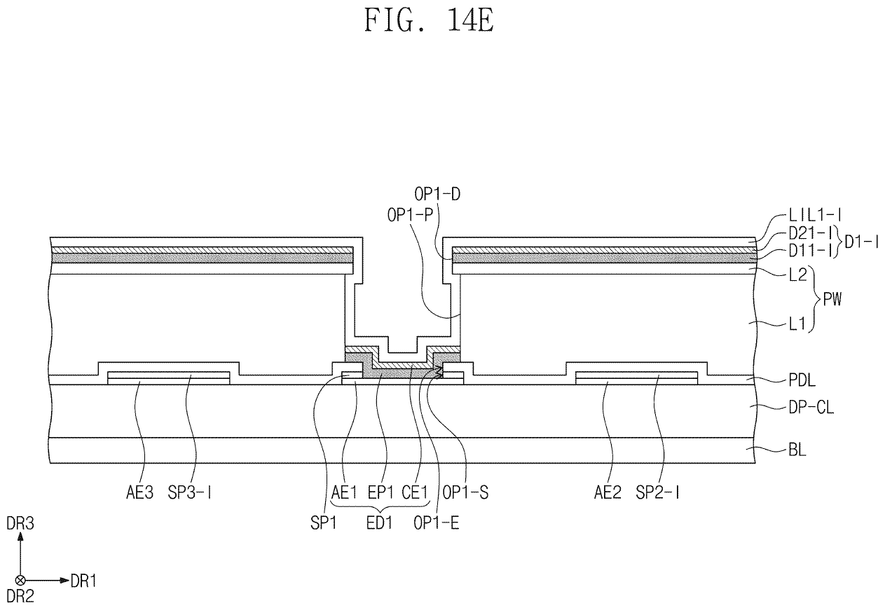

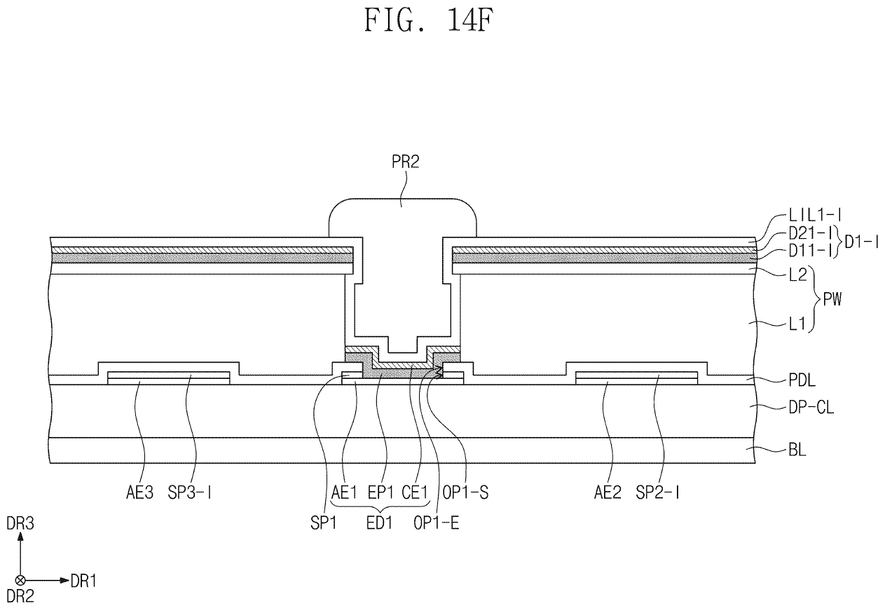

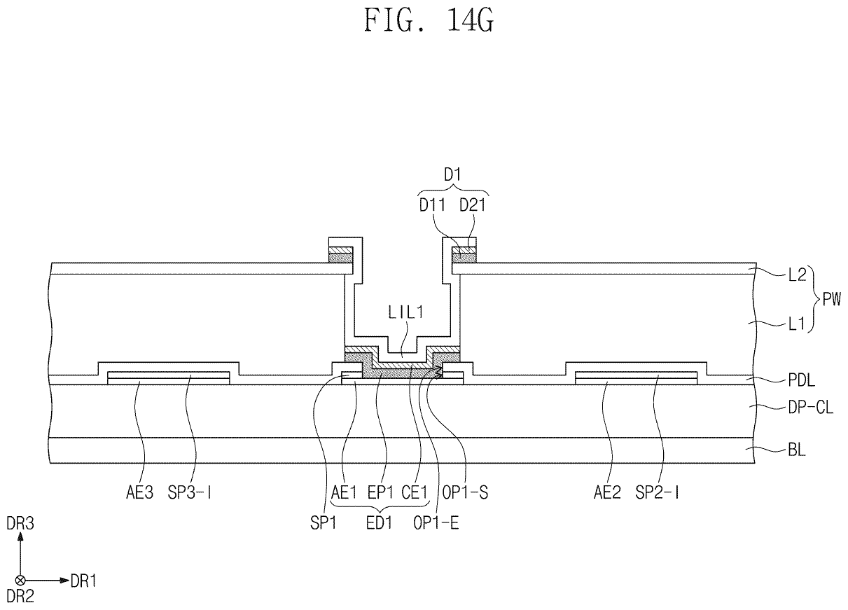

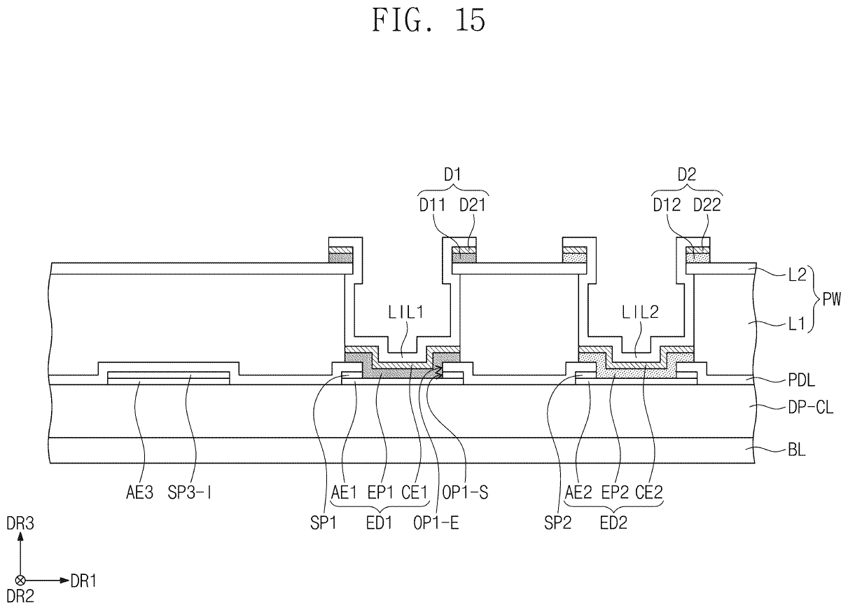

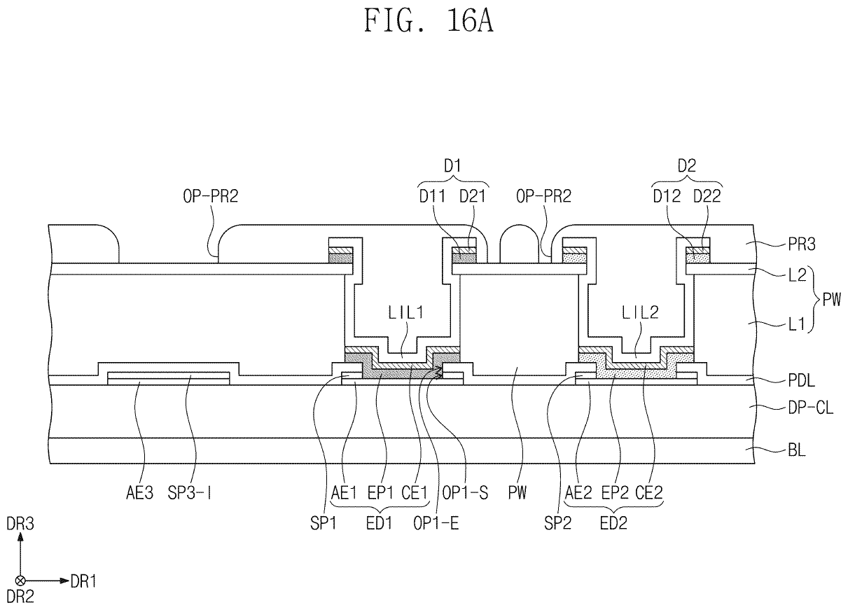

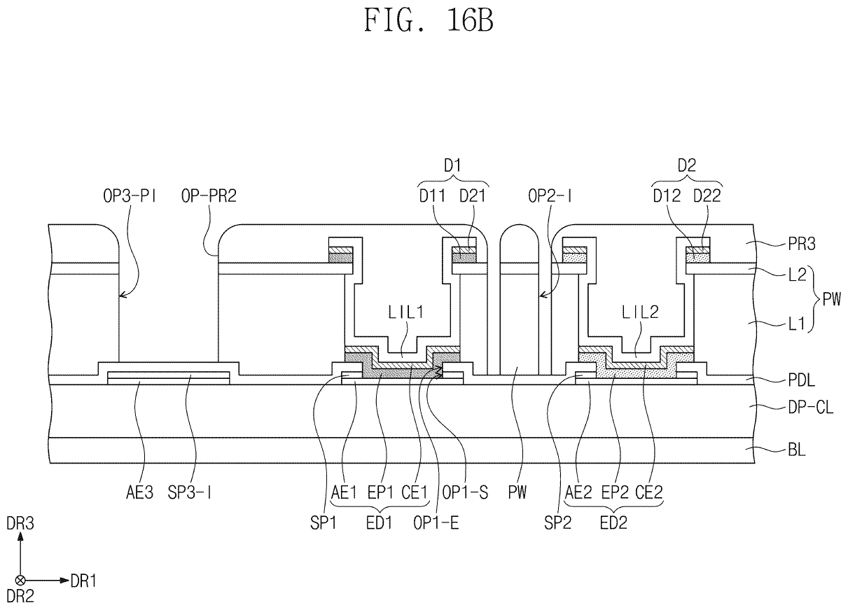

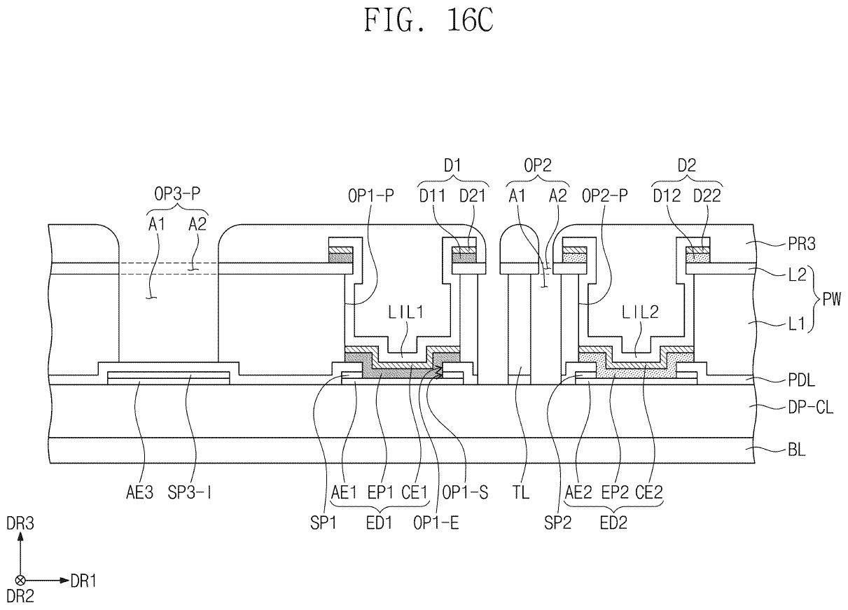

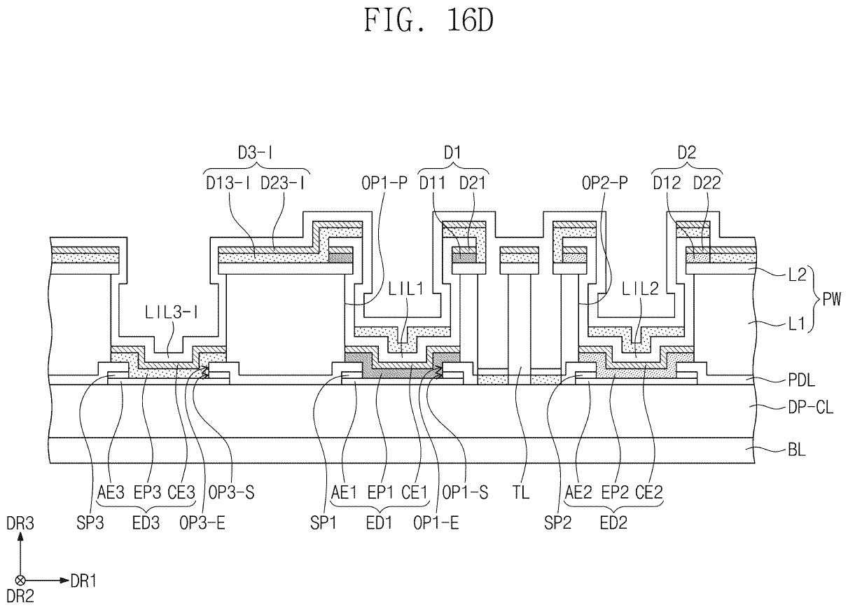

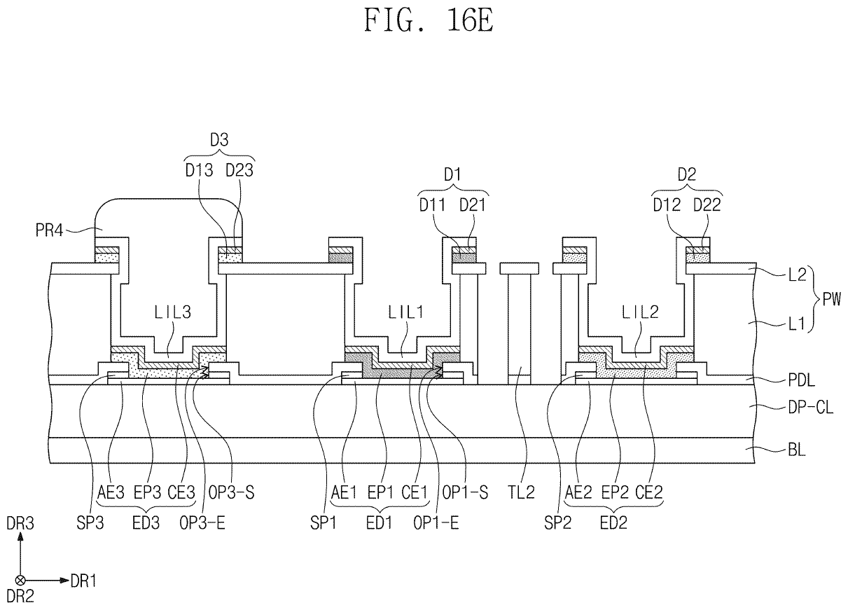

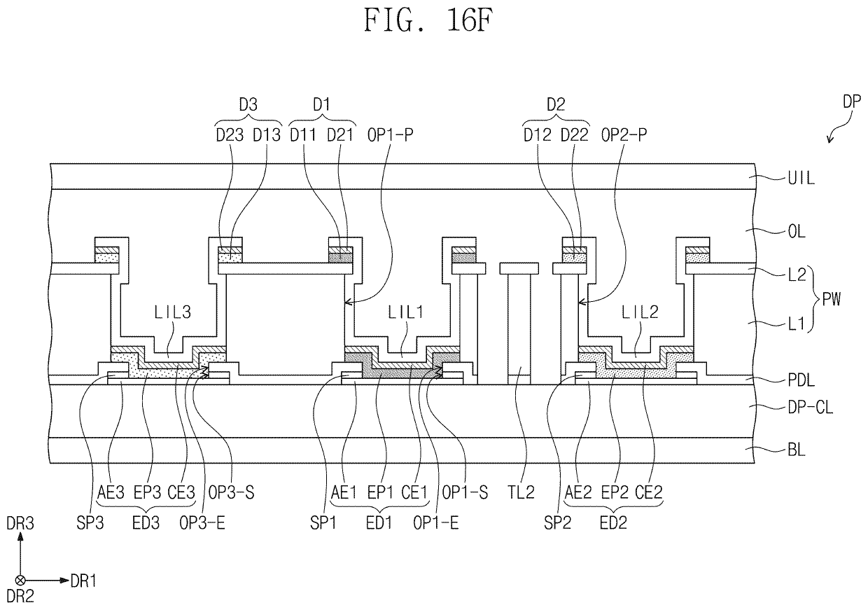

FIGS. 14A to 14G are sectional views illustrating a part of processes of a display panel manufacturing method according to an embodiment of the disclosure. FIG. 15 is a sectional view illustrating a part of the processes of the display panel manufacturing method according to an embodiment of the disclosure. FIGS. 16A to 16F are sectional views illustrating a part of the processes of the display panel manufacturing method according to an embodiment of the disclosure. In describing FIGS. 14A to 16F, elements or components identical/similar to the elements or components described above with reference to FIGS. 1 to 7 will be assigned with identical/similar reference numerals, and repetitive detailed descriptions thereof will be omitted.

An embodiment of the display panel manufacturing method according to the disclosure may include a first group process, a second group process, a third group process, and a fourth group process. The first to third group processes may be processes of forming the first to third light emitting elements ED1, ED2, and ED3 (refer to FIG. 16F) and some components of the thin film encapsulation layer TFE (refer to FIG. 16F), and the fourth group process may be a process of completing the display panel DP (refer to FIG. 16F) by forming the remaining components of the thin film encapsulation layer TFE (refer to FIG. 16F).

In an embodiment, the first light emitting element ED1 (refer to FIG. 14G) and the first lower inorganic encapsulation pattern LIL1 (refer to FIG. 14G) that covers the first light emitting element ED1 may be formed through the first group process. Hereinafter, the first group process will be described with reference to FIGS. 14A and 14G.

Referring to FIG. 14A, the display panel manufacturing method according to an embodiment may include a process of providing or preparing a preliminary display panel DP-I and a process of forming a first photoresist layer PR1 on the preliminary display panel DP-I. In such an embodiment, the preliminary display panel DP-I may include the base layer BL, the circuit layer DP-CL, the first to third anodes AE1, AE2, and AE3, first to third preliminary sacrificial patterns SP1-I, SP2-I, and SP3-I, the pixel defining layer PDL, and the barrier wall PW.

The circuit layer DP-CL may be formed through a conventional circuit element manufacturing process of forming an insulating layer, a semiconductor layer, and a conductive layer by coating, deposition, or the like and forming a semiconductor pattern, a conductive pattern, and a signal line by selectively making the insulating layer, the semiconductor layer, and the conductive layer subject to patterning by photolithography and etching processes. The first to third anodes AE1, AE2, and AE3 and the first to third preliminary sacrificial patterns SP1-I, SP2-I, and SP3-I may be formed by a same patterning process.

The pixel defining layer PDL may be formed on the first to third preliminary sacrificial patterns SP1-I, SP2-I, and SP3-I to cover the first to third preliminary sacrificial patterns SP1-I, SP2-I, and SP3-I. The barrier wall PW may be formed on the pixel defining layer PDL. A process of forming the barrier wall PW may include a process of forming the first barrier wall layer L1 and a process of forming the second barrier wall layer L2.

The process of forming the first barrier wall layer L1 may be performed by a process of depositing a conductive material. The first barrier wall layer L1 may be formed on the pixel defining layer PDL. The process of forming the second barrier wall layer L2 may be performed by a process of depositing a conductive material. The second barrier wall layer L2 may be formed on the first barrier wall layer L1.

The display panel manufacturing method according to an embodiment may include a process of forming the first photoresist layer PR1 on the barrier wall PW. The first photoresist layer PR1 may be formed by forming a preliminary photoresist layer on the barrier wall PW and thereafter making the preliminary photoresist layer subject to patterning by using a photo mask. Through the patterning process, a first photo opening OP-PR1 overlapping the first anode AE1 may be formed in the first photoresist layer PR1.

Referring to FIGS. 14B and 14C, the display panel manufacturing method may include a process of forming the barrier wall PW having the first barrier opening OP1-P defined therein by etching the barrier wall PW. The process of forming the barrier wall PW may include a process of etching the first barrier wall layer L1 and the second barrier wall layer L2.

As illustrated in FIG. 14B, a process of firstly etching the first barrier wall layer L1 and the second barrier wall layer L2 may include a process of forming a first preliminary barrier opening OP1-PI in the barrier wall PW by dry etching the first barrier wall layer L1 and the second barrier wall layer L2 using the first photoresist layer PR1 as a mask.

The first dry etching process in an embodiment may be performed in an etching environment in which the etch selectivity between the first barrier wall layer L1 and the second barrier wall layer L2 is about 1, that is, the etch rates of the first barrier wall layer L1 and the second barrier wall layer L2 are substantially the same as each other. Accordingly, the inner surface of the first barrier wall layer L1 and the inner surface of the second barrier wall layer L2 that define the first preliminary barrier opening OP1-PI may be substantially aligned with each other.

As illustrated in FIG. 14C, a process of secondly etching the first barrier wall layer L1 may include a process of forming the first barrier opening OP1-P from the first preliminary barrier opening OP1-PI (refer to FIG. 14B) by wet etching the first barrier wall layer L1 using the first photoresist layer PR1 as a mask.

The first barrier opening OP1-P may include a first region A1 and a second region A2 sequentially disposed in a thickness direction (that is, the third direction DR3). The first barrier wall layer L1 may include a first inner surface that defines the first region A1 of the first barrier opening OP1-P, and the second barrier wall layer L2 may include a second inner surface that defines the second region A2 of the first barrier opening OP1-P. The first barrier opening OP1-P may overlap the first anode AE1.

The second wet etching process in an embodiment may be performed in an environment in which the etch selectivity between the first barrier wall layer L1 and the second barrier wall layer L2 is large or greater than 1. Accordingly, the inner surface of the barrier wall PW that defines the first barrier opening OP1-P may have an undercut shape on the section. In such an embodiment, the first barrier wall layer L1 may be mainly etched since the etch rate of the first barrier wall layer L1 by an etching solution is higher than the etch rate of the second barrier wall layer L2. Accordingly, the first inner surface of the first barrier wall layer L1 may be further recessed inward, compared to the second inner surface of the second barrier wall layer L2. A tip portion may be formed on the barrier wall PW by a portion of the second barrier wall layer L2 that protrudes from the first barrier wall layer L1.

Referring to FIG. 14D, the display panel manufacturing method according to this embodiment may include a process of etching the pixel defining layer PDL to form the first light emitting opening OP1-E and a process of etching the first preliminary sacrificial pattern SP1-I to form the first sacrificial opening OP1-S.

The process of etching the pixel defining layer PDL may be performed by a dry etching method and may be performed using the first photoresist layer PR1 and the barrier wall PW (e.g., the second barrier wall layer L2) as a mask. The first light emitting opening OP1-E overlapping the first barrier opening OP1-P may be defined in the pixel defining layer PDL.

The process of etching the first preliminary sacrificial pattern SP1-I (refer to FIG. 14C) may be performed by a wet etching method and may be performed using the first photoresist layer PR1 and the barrier wall PW (e.g., the second barrier wall layer L2) as a mask. The first sacrificial opening OP1-S overlapping the first light emitting opening OP1-E may be formed in the first sacrificial pattern SP1 formed by etching the first preliminary sacrificial pattern SP1-I. At least a portion of the first anode AE1 may be exposed from the first sacrificial pattern SP1 and the pixel defining layer PDL by the first sacrificial opening OP1-S and the first light emitting opening OP1-E.

The process of etching the first sacrificial pattern SP1 may be performed in an environment in which the etch selectivity between the first sacrificial pattern SP1 and the first anode AE1 is large. Accordingly, the first anode AE1 may be effectively prevented from being etched together. That is, the first sacrificial pattern SP1 having a higher etch rate than the first anode AE1 may be disposed between the pixel defining layer PDL and the first anode AE1, and thus the first anode AE1 may be prevented from being etched and damaged together during the etching process.

Referring to FIG. 14E, the display panel manufacturing method according to this embodiment may include a process of forming the first emission pattern EP1 after removing the first photoresist layer PR1 (refer to FIG. 14D), a process of forming the first cathode CE1, and a process of forming a first lower inorganic encapsulation film LIL1-I.

The process of forming the first emission pattern EP1 and the process of forming the first cathode CE1 may be performed by a deposition process. In an embodiment, the process of forming the first emission pattern EP1 may be performed by a thermal evaporation process, and the process of forming the first cathode CE1 may be performed by a sputtering process. However, the disclosure is not limited thereto.

In the process of forming the first emission pattern EP1, the first emission pattern EP1 may be separated by the tip portion formed on the barrier wall PW and may be disposed in the first light emitting opening OP1-E and the first barrier opening OP1-P. In the process of forming the first emission pattern EP1, a first first dummy layer (hereinafter, will be referred to as “dummy layer 1-1”) D11-I spaced apart from the first emission pattern EP1 may be formed on the barrier wall PW together.

In the process of forming the first cathode CE1, the first cathode CE1 may be separated by the tip portion formed on the barrier wall PW and may be disposed in the first barrier opening OP1-P. The first cathode CE1 may be provided at a higher incident angle than the first emission pattern EP1 and thus may contact (or be in contact with) the first inner surface of the first barrier wall L1. In the process of forming the first cathode CE1, a second first dummy layer (hereinafter, will be referred to as “dummy layer 2-1”) D21-I spaced apart from the first cathode CE1 may be formed on the barrier wall PW together. The first anode AE1, the first emission pattern EP1, and the first cathode CE1 may constitute (or collectively define) the first light emitting element ED1.

Although not illustrated in FIG. 14E, the display panel manufacturing method according to an embodiment may further include a process of forming a first capping pattern on the first cathode CE1. The process of forming the first capping pattern may be performed by a deposition process. In an embodiment, for example, the process of forming the first capping pattern may be performed by a thermal evaporation process. In the process of forming the first capping pattern, the first capping pattern may be separated by the tip portion formed on the barrier wall PW and may be disposed in the first barrier opening OP1-P. In the process of forming the first capping pattern, a third first dummy layer (hereinafter, will be referred to as “dummy layer 3-1”) spaced apart from the first capping pattern may be formed on the barrier wall PW together.

The dummy layer 1-1 D11-I and the dummy layer 2-1 D21-I may form a first dummy layer D1-I, and a first dummy opening OP1-D may be formed in the first dummy layer D1-I.

The first lower inorganic encapsulation film LIL1-I may be formed through a deposition process. In an embodiment, the first lower inorganic encapsulation film LIL1-I may be formed through a chemical vapor deposition (CVD) process. The first lower inorganic encapsulation film LIL1-I may be formed on the barrier wall PW and the first cathode CE1, and a portion of the first lower inorganic encapsulation film LIL1-I may be formed in the first barrier opening OP1-P.

Referring to FIG. 14F, the display panel manufacturing method according to an embodiment may include a process of forming a second photoresist layer PR2. In the process of forming the second photoresist layer PR2, the second photoresist layer PR2 may be formed by forming a preliminary photoresist layer and making the preliminary photoresist layer subject to patterning by using a photo mask. Through the patterning process, the second photoresist layer PR2 may be formed in a pattern form corresponding to the first light emitting opening OP1-E.

Referring to FIGS. 14F and 14G, the display panel manufacturing method according to this embodiment may include a process of making the first lower inorganic encapsulation film LIL1-I (refer to FIG. 14F) subject to patterning to form the first lower inorganic encapsulation pattern LIL1 and a process of making the first dummy layer D1-I subject to patterning to form the first dummy patterns D1.

The process of making the first lower inorganic encapsulation film LIL1-I subject to patterning may be performed in a way such that portions of the first lower inorganic encapsulation film LIL1-I that overlap the second and third anodes AE2 and AE3 other than the first anode AE1 are removed by dry etching the first lower inorganic encapsulation film LIL1-I. The first lower inorganic encapsulation pattern LIL1 overlapping the first light emitting opening OP1-E may be formed from the patterned first lower inorganic encapsulation film LIL1-I. One portion of the first lower inorganic encapsulation pattern LIL1 may be disposed in the first barrier opening OP1-P and may cover the first light emitting element ED1, and another portion of the first lower inorganic encapsulation pattern LIL1 may be disposed on the barrier wall PW.

The process of making the first dummy layer D1-I subject to patterning may be performed in a way such that a portion of the dummy layer 1-1 D11-I and a portion of the dummy layer 2-1 D21-I that overlap the second and third anodes AE2 and AE3 other than the first anode AE1 are removed by dry etching the dummy layer 1-1 D11-I and the dummy layer 2-1 D21-I. The dummy pattern 1-1 D11 and the dummy pattern 2-1 D21 that overlap the first light emitting opening OP1-E may be formed from or defined by the patterned dummy layer 1-1 D11-I and the patterned dummy layer 2-1 D21-I, and thus the first dummy patterns D1 including the dummy pattern 1-1 D11 and the dummy pattern 2-1 D21 may be formed. The dummy pattern 1-1 D11 and the dummy pattern 2-1 D21 may have a closed-line shape surrounding the first emissive region PXA-R (refer to FIG. 5) on the plane.

The second group process may be performed after the first group process. Referring to FIG. 15, the second light emitting element ED2 and the second lower inorganic encapsulation pattern LIL2 covering the second light emitting element ED2 may be formed through the second group process. The process of forming the second light emitting element ED2 and the second lower inorganic encapsulation pattern LIL2 may be substantially the same as the process of forming the first light emitting element ED1 and the first lower inorganic encapsulation pattern LIL1, which has been described above with reference to FIGS. 14A to 14G. Therefore, any repetitive detailed description of the second group process will be omitted.

The third group process may be performed after the second group process. The third light emitting element ED3 (refer to FIG. 16E), the third lower inorganic encapsulation pattern LIL3 (refer to FIG. 16E) that covers the third light emitting element ED3, and the second trace line TL2 (refer to FIG. 16E) may be formed through the third group process. Hereinafter, the third group process will be described with reference to FIGS. 16A to 16E.

Referring to FIG. 16A, the display panel manufacturing method according to an embodiment may include a process of forming a third photoresist layer PR3 on the barrier wall PW. The third photoresist layer PR3 may be formed by forming a preliminary photoresist layer on the barrier wall PW and thereafter making the preliminary photoresist layer subject to patterning by using a photo mask. Through the patterning process, a second photo opening OP-PR2 that overlaps the third anode AE3 and overlaps the barrier wall PW disposed between the first anode AE1 and the second anode AE2 may be formed in the third photoresist layer PR3. The barrier wall PW may be one of the plurality of barrier wall patterns PW1, PW2, PW3, PW4, and PW5 of FIG. 5.

Referring to FIGS. 16B and 16C, the display panel manufacturing method may include a process of forming the barrier wall PW having the third barrier opening OP3-P and the second opening OP2 defined therein by etching the barrier wall PW. The process of forming the barrier wall PW may include a process of etching the first barrier wall layer L1 and the second barrier wall layer L2.

As illustrated in FIG. 16B, a process of firstly etching the first barrier wall layer L1 and the second barrier wall layer L2 may include a process of forming a third preliminary barrier opening OP3-PI and a second preliminary opening OP2-I in the barrier wall PW by dry etching the first barrier wall layer L1 and the second barrier wall layer L2 using the third photoresist layer PR3 as a mask.

The first dry etching process in this embodiment may be performed in an etching environment in which the etch selectivity between the first barrier wall layer L1 and the second barrier wall layer L2 is substantially 1. Accordingly, the inner surface of the first barrier wall layer L1 and the inner surface of the second barrier wall layer L2 that define the third preliminary barrier opening OP3-PI may be substantially aligned with each other.

As illustrated in FIG. 16C, a process of secondly etching the first barrier wall layer L1 may include a process of forming the third barrier opening OP3-P and the second opening OP2 from the third preliminary barrier opening OP3-PI (refer to FIG. 16B) and the second preliminary opening OP2-I (refer to FIG. 16B) by wet etching the first barrier wall layer L1 using the third photoresist layer PR3 as a mask.

The third barrier opening OP3-P and the second opening OP2 may include a first region A1 and a second region A2 sequentially disposed in the thickness direction (that is, the third direction DR3). The first barrier wall layer L1 may include a first inner surface that defines the first regions A1 of the third barrier opening OP3-P and the second opening OP2, and the second barrier wall layer L2 may include a second inner surface that defines the second regions A2 of the third barrier opening OP3-P and the second opening OP2. The third barrier opening OP3-P may overlap the third anode AE3, and the second opening OP2 may overlap the barrier wall PW between the first anode AE1 and the second anode AE2.

The second wet etching process in an embodiment may be performed in an environment in which the etch selectivity between the first barrier wall layer L1 and the second barrier wall layer L2 is large. Accordingly, the inner surface of the barrier wall PW that defines the third barrier opening OP3-P may have an undercut shape on the section. In such an embodiment, the first barrier wall layer L1 may be mainly etched since the etch rate of the first barrier wall layer L1 by an etching solution is higher than the etch rate of the second barrier wall layer L2. Accordingly, the first inner surface of the first barrier wall layer L1 may be further recessed inward, compared to the second inner surface of the second barrier wall layer L2. A tip portion may be formed on the barrier wall PW by a portion of the second barrier wall layer L2 that protrudes from the first barrier wall layer L1.

Referring to FIGS. 16B and 16C, a trace line TL may be formed by etching the barrier wall PW. The trace line TL may be formed through one of the processes of forming the first to third barrier openings OP1-P, OP2-P, and OP3-P. In an embodiment, for example, the trace line TL may be formed through a process that is the same as the process through which the last one of the first to third barrier openings OP1-P, OP2-P, and OP3-P is formed. Accordingly, the number of times that the trace line TL is exposed to an etching environment may be reduced, and a residue (e.g., the first photoresist layer PR1) may be effectively prevented from remaining between the trace line TL and the adjacent second opening OP2. In FIGS. 14A to 16G, the trace line TL formed through a same process as the third barrier opening OP3-P formed last is illustrated as an example. However, the disclosure is not limited thereto. The trace line TL may be one of the plurality of trace lines TL1, TL2, TL3, TL4, and TL5 of FIG. 5.

Referring to FIG. 16D, the display panel manufacturing method according to this embodiment may include a process of etching the pixel defining layer PDL to form the first light emitting opening OP3-E, a process of etching the third preliminary sacrificial pattern SP3-I (refer to FIG. 16C) to form the third sacrificial opening OP3-S, a process of removing the third photoresist layer PR3 (refer to FIG. 16C), a process of forming the third emission pattern EP3, a process of forming the third cathode CE3, and a process of forming a third lower inorganic encapsulation film LIL3-I.

The process of etching the pixel defining layer PDL, the process of etching the third preliminary sacrificial pattern SP3-I, the process of removing the third photoresist layer PR3, the process of forming the third emission pattern EP3, the process of forming the third cathode CE3, and the process of forming the third lower inorganic encapsulation film LIL3-I, which are illustrated in FIG. 16D, may be substantially the same as the process of etching the pixel defining layer PDL, the process of etching the first preliminary sacrificial pattern SP1-I, the process of removing the first photoresist layer PR1, the process of forming the first emission pattern EP1, the process of forming the first cathode CE1, and the process of forming the first lower inorganic encapsulation film LIL1-I that are illustrated in FIGS. 14D to 14E.

Referring to FIG. 16E, the display panel manufacturing method according to this embodiment may include a process of forming a fourth photoresist layer PR4, a process of making the third lower inorganic encapsulation film LIL3-I (refer to FIG. 16D) subject to patterning to form the third lower inorganic encapsulation pattern LIL3, and a process of making a third dummy layer D3-I subject to patterning to form the third dummy patterns D3.

In the process of forming the fourth photoresist layer PR4, the fourth photoresist layer PR4 may be formed by forming a preliminary photoresist layer and making the preliminary photoresist layer subject to patterning by using a photo mask. Through the patterning process, the fourth photoresist layer PR4 may be formed in a pattern form corresponding to the third light emitting opening OP3-E.

The process of making the third lower inorganic encapsulation film LIL3-I subject to patterning may be performed in a way such that portions of the third lower inorganic encapsulation film LIL3-I that overlap the first and second anodes AE1 and AE2 other than the third anode AE3 are removed by dry etching the third lower inorganic encapsulation film LIL3-I. The third lower inorganic encapsulation pattern LIL3 overlapping the third light emitting opening OP3-E may be formed from the patterned third lower inorganic encapsulation film LIL3-I. One portion of the third lower inorganic encapsulation pattern LIL3 may be disposed in the third barrier opening OP3-P and may cover the third light emitting element ED3, and another portion of the third lower inorganic encapsulation pattern LIL3 may be disposed on the barrier wall PW.

The process of making the third dummy layer D3-I subject to patterning may be performed in a way such that a portion of a dummy layer 1-3 D13-I and a portion of a dummy layer 2-3 D23-I that overlap the first and second anodes AE1 and AE2 other than the third anode AE3 are removed by dry etching the dummy layer 1-3 D13-I and the dummy layer 2-3 D23-I. The dummy pattern 1-3 D13 and the dummy pattern 2-3 D23 that overlap the third light emitting opening OP3-E may be formed from the patterned dummy layer 1-3 D13-I and the patterned dummy layer 2-3 D23-I, and thus the third dummy patterns D3 including the dummy pattern 1-3 D13 and the dummy pattern 2-3 D23 may be formed. The dummy pattern 1-3 D13 and the dummy pattern 2-3 D23 may have a closed-line shape surrounding the third emissive region PXA-B (refer to FIG. 5) on the plane.

The fourth group process may be performed after the first to third light emitting elements ED1, ED2, and ED3 and the first to third lower inorganic encapsulation patterns LIL1, LIL2, and LIL3 are formed through the first to third group processes. The display panel DP (refer to FIG. 16F) including the thin film encapsulation layer TFE (refer to FIG. 16F) may be completed through the fourth group process.

Referring to FIG. 16F, the fourth group process may include a process of forming the organic encapsulation film OL on the barrier wall PW and the first to third lower inorganic encapsulation patterns LIL1, LIL2, and LIL3 and a process of forming the upper inorganic encapsulation film UIL on the organic encapsulation film OL. Accordingly, the display panel DP including the base layer BL, the circuit layer DP-CL, the display element layer DP-OLED, and the thin film encapsulation layer TFE may be formed.

In embodiments of the disclosure, as described above, the display device may include the plurality of touch electrodes disposed between the circuit layer and the thin film encapsulation layer instead of a separate input sensing layer. Thus, the weight or thickness of the display device may be decreased.

In embodiments of the disclosure, by patterning the plurality of emission patterns without a mask in contact with an internal component in the display region, a defect rate may be reduced, and thus the display panel having improved process reliability may be provided. Since patterning is possible even though a separate spacer for support that protrudes from the barrier wall is not provided, the areas of the emissive regions may be scaled down, and thus the display panel capable of easily implementing high resolution may be provided.

In embodiments of the disclosure, in the manufacture of the large-area display panel, the manufacture of a large-area mask may be omitted. Accordingly, process costs may be reduced, and the display panel may not be affected by defects that are likely to occur in the large-area mask. Thus, the display panel having improved process reliability may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a base layer;
a circuit layer disposed on the base layer;
an anode disposed on the circuit layer;
a pixel defining layer disposed on the circuit layer, wherein a light emitting opening is defined in the pixel defining layer to overlap the anode;
a barrier wall disposed on the pixel defining layer, wherein a barrier opening is defined in the barrier wall to overlap the light emitting opening;
a thin film encapsulation layer disposed over the circuit layer to cover the anode, the pixel defining layer, and the barrier wall; and
a plurality of touch electrodes disposed between the circuit layer and the thin film encapsulation layer.

2. The display device of claim 1, further comprising:
an emission pattern disposed on the anode; and
a cathode disposed on the emission pattern and in contact with the barrier wall.

3. The display device of claim 2, wherein the cathode includes a plurality of cathodes, and each of the plurality of touch electrodes includes a corresponding cathode among the plurality of cathodes.

4. The display device of claim 1, wherein the barrier wall includes a plurality of barrier wall patterns spaced apart from each other.

5. The display device of claim 4, wherein each of the plurality of touch electrodes includes a corresponding barrier wall pattern among the plurality of barrier wall patterns.

6. The display device of claim 1, wherein
a common voltage is provided to the plurality of touch electrodes in a first mode, and
a touch sensing signal is provided to the plurality of touch electrodes in a second mode different from the first mode.

7. The display device of claim 6, wherein
each of the plurality of touch electrodes is electrically connected with a first transistor and a second transistor, and
the first transistor transfers the common voltage to the plurality of touch electrodes in the first mode and transfers the touch sensing signal to the plurality of touch electrodes in the second mode.

8. The display device of claim 1, further comprising:
a plurality of trace lines electrically connected with the plurality of touch electrodes.

9. The display device of claim 8, wherein each of the plurality of trace lines is disposed in a same layer as the anode and includes a same material as the anode.

10. The display device of claim 8, wherein each of the plurality of trace lines includes:
a first sub-layer disposed in a same layer as the anode and including a same material as the anode; and
a second sub-layer disposed under the first sub-layer and electrically connected with the first sub-layer, wherein the second sub-layer is included in the circuit layer.

11. The display device of claim 1, wherein the plurality of touch electrodes are disposed over the barrier wall and insulated from the barrier wall.

12. The display device of claim 11, further comprising:
an insulating layer disposed between the plurality of touch electrodes and the barrier wall.

13. The display device of claim 1, wherein the plurality of touch electrodes include a first touch electrode and a second touch electrode, and
wherein the first touch electrode includes a sensing pattern and a bridge pattern, and the bridge pattern is disposed in a same layer as the anode and includes a same material as the anode.

14. The display device of claim 1, further comprising:
a protrusion surrounding at least a portion of a hole defined in the base layer in a plan view,
wherein the protrusion includes a same material as the barrier wall.

15. A display device comprising:
a base layer;
a circuit layer disposed on the base layer;
a plurality of anodes disposed on the circuit layer;
a pixel defining layer disposed on the circuit layer, wherein light emitting openings are defined in the pixel defining layer to overlap the plurality of anodes;
a barrier wall disposed on the pixel defining layer, wherein barrier openings are defined in the barrier wall to overlap the light emitting openings;
a plurality of intermediate layers disposed on the plurality of anodes and accommodated in the light emitting openings; and
an electrode layer disposed on the plurality of intermediate layers,
wherein a common voltage is provided to the electrode layer in a first mode, and
a touch sensing signal is provided to the electrode layer in a second mode different from the first mode.

16. The display device of claim 15, wherein the barrier wall includes a plurality of barrier wall patterns spaced apart from each other, and
wherein the electrode layer includes a plurality of touch electrodes, each of which is electrically connected with a corresponding barrier wall pattern among the plurality of barrier wall patterns.

17. The display device of claim 16, wherein
each of the plurality of touch electrodes is electrically connected with a first transistor and a second transistor, and
the first transistor transfers the common voltage to the plurality of touch electrodes in the first mode and transfers the touch sensing signal to the plurality of touch electrodes in the second mode.

18. The display device of claim 16, further comprising:
a plurality of trace lines electrically connected with the plurality of touch electrodes,
wherein each of the plurality of trace lines are disposed in a same layer as the plurality of anodes and include a same material as the plurality of anodes.

19. The display device of claim 16, further comprising:
a plurality of trace lines electrically connected with the plurality of touch electrodes,
wherein each of the plurality of trace lines includes:
a first sub-layer disposed in a same layer as the plurality of anodes and including a same material as the plurality of anodes; and
a second sub-layer disposed under the first sub-layer and electrically connected with the first sub-layer, wherein the second sub-layer is included in the circuit layer.

20. The display device of claim 16, wherein the plurality of touch electrodes include a first touch electrode and a second touch electrode, and
wherein the first touch electrode includes a sensing pattern and a bridge pattern, and the bridge pattern is disposed in a same layer as the plurality of anodes and includes a same material as the plurality of anodes.

21. The display device of claim 15, further comprising
a protrusion surrounding at least a portion of a hole defined in the base layer in a plan view,
wherein the protrusion includes a same material as the barrier wall.
